(19) United States
(12) Patent Application Publication
(10) Pub. No.: US 2026/0331033 A1
(43) Pub. Date: Oct. 22, 2026

(54) Display Device and Driving Method thereof

(71) Applicant: LG Display Co., Ltd., Seoul (KR)

(72) Inventor: Daeseok OH, Paju-si (KR)

(73) Assignee: LG Display Co., Ltd., Seoul (KR)

(21) Appl. No.: 19/446,022

(22) Filed: Jan. 12, 2026

(30) Foreign Application Priority Data
Apr. 16, 2025 (KR) 10-2025-0049646

(51) Int. Cl. G09G 3/32

(52) U.S. Cl. CPC G09G 3/32; G09G 2300/0408; G09G 2310/0275; G09G 2310/0291; G09G 2310/0297; G09G 2330/021

(57) ABSTRACT

Disclosed are a display device, including: a display panel having a pixel; a data driver integrated circuit including an output buffer connected to an output channel, the data driver configured to output a data voltage to the pixel through a data line; and a multiplexer connected between the output channel and the data line, the multiplexer including a switching element controlled by a mux control signal, and a method for driving the same.

### CROSS REFERENCE TO RELATED APPLICATION

This application claims the benefit of and priority to Korean Patent Application No. 10-2025-0049646, filed Apr. 16, 2025, the entire contents of which are incorporated herein by reference for all purposes.

### BACKGROUND

### 1. Technical Field

The present disclosure relates to a display device and a method for driving the same.

### 2. Description of Related Art

With the development of an information-oriented society, various demands for display devices for displaying images have increased, and various types of display devices, such as liquid crystal display devices (LCD), plasma display panel devices (PDP) and organic light emitting display devices (OLED) have been used.

A typical display device does not limit a viewing angle. However, the limitation of the viewing angle of the display device is recently required for the reasons of privacy and information protection. For example, in the case of a display device used as an information medium inside a vehicle, a high-definition image is provided to a passenger in a front passenger seat, but a viewing angle needs to be limited to a driver for safety while driving.

The description of related art should not be considered prior art merely because it is mentioned in or associated with this section. The description of related art includes information that describes one or more aspects of the subject technology, and the description in this section does not limit the scope of the present disclosure.

### SUMMARY

Example embodiments of the present disclosure provide a display device capable of displaying a privacy image and a share image in a plurality of regions on a display panel, separately, and a method for driving the same.

Example embodiments of the present disclosure provide a display device which provides a dummy data voltage to some of sub-pixels according to a privacy mode or a share mode and deactivates an output buffer, or a data driver integrated circuit connected to sub-pixels to which a dummy data voltage is provided and a method for driving the same.

Example embodiments of the present disclosure provide a display device which includes a data driver integrated circuit, of which an output channel is connected to a ground voltage and a method for driving the same.

Example embodiments of the present disclosure provide a display device which includes a multiplexer having a dummy switching element configured to connect a dummy voltage line and a data line to each other in response to a dummy mux control signal and a method for driving the same. One example embodiment provides a display device, including: a display panel having a pixel; a data driver integrated circuit including an output buffer connected to an output channel, the data driver configured to output a data voltage to the pixel through a data line; and a multiplexer connected between the output channel and the data line, the multiplexer including a switching element controlled by a mux control signal.

The pixel may include: a first sub-pixel connected to a first data line; and a second sub-pixel connected to a second data line, the second sub-pixel configured to display a color that is identical to a color of the first sub-pixel

The data driver integrated circuit may be configured to output a first data voltage in correspondence with a first image to the first sub-pixel and output a dummy data voltage to the second sub-pixel when the pixel is operated in a first mode, and output the dummy data voltage to the first sub-pixel and output a second data voltage in correspondence with a second image to the second sub-pixel when the pixel is operated in a second mode.

The output channel may be further connected to a node for a ground voltage.

The output channel may be configured to output the first data voltage output from the output buffer to the first sub-pixel and output the ground voltage to the second sub-pixel when the pixel is operated in the first mode, and output the ground voltage to the first sub-pixel and output the second data voltage output from the output buffer to the second sub-pixel when the pixel is operated in the second mode.

The output buffer may be activated according to a source output enable signal at a turn-on level input from an external device, and the source output enable signal may be applied in a turn-off level while the ground voltage is output from the output channel.

The multiplexer may include: a first switching element configured to be turned on according to a first mux control signal and connect the output channel to the first sub-pixel; a second switching element configured to be turned on according to a second mux control signal and connect the output channel to the second sub-pixel; a first dummy switching element configured to be turned on according to a first dummy mux control signal and connect a dummy voltage line receiving the dummy data voltage and the first data line to each other; and a second dummy switching element configured to be turned on according to a second dummy mux control signal and connect the dummy voltage line and the second data line to each other.

The dummy data voltage may be a voltage in correspondence with a black gray scale.

The second dummy mux control signal at a turn-on level may be applied when the pixel is operated in the first mode, and the first dummy mux control signal at a turn-on level may be applied when the pixel is operated in the second mode.

The data driver integrated circuit may be activated according to a data driver enable signal input from an external device, and the data driver enable signal at a turn-off level may be applied in response to the first dummy mux control signal at a turn-on level or the second dummy mux control signal at a turn-on level.

The display panel may include: a first unit pixel and a second unit pixel, each of which includes two or more pixels.

The multiplexer may include: a first switching element configured to be turned on according to a first-first mux control signal and connect the output channel to the first sub-pixel of the first unit pixel; a second switching element configured to be turned on according to a second-first mux control signal and connect the output channel to the second sub-pixel of the first unit pixel; a third switching element configured to be turned on according to a first-second mux control signal and connect the output channel to the first sub-pixel of the second unit pixel; and a fourth switching element configured to be turned on according to a second-second mux control signal and connect the output channel to the second sub-pixel of the second unit pixel.

The display panel may include: a first region in which the first image is displayed using the first sub-pixel; and a second region in which the second image different from the first image is displayed using the second sub-pixel, and the first region and the second region may be varied while the display panel is driven.

The first sub-pixel and the second sub-pixel may have an identical pixel structure, and the first sub-pixel and the second sub-pixel may have a mirrored shape along a pixel column direction.

The display panel may further comprise a lens member, the lens member including a plurality of lenses.

The lens member may include: a first lens disposed in a first light emitting region of the first sub-pixel; and a second lens disposed in a second light emitting region of the second sub-pixel, the second lens having a shape different from a shape of the first lens.

The first lens may be configured to control to emit light, emitted from the first light emitting region, at a first viewing angle, and the second lens may be configured to control to emit light, emitted from the second light emitting region, at a second viewing angle wider than the first viewing angle.

One or more aspects of the present disclosure provide a method for driving a display device, including: outputting, by the data driver integrated circuit, the data voltage to the first sub-pixel in a first period within one horizontal period; and outputting, by the data driver integrated circuit, the data voltage to the second sub-pixel in a second period within the one horizontal period.

When the pixel is operated in a first mode, the outputting the data voltage to the first sub-pixel may include: outputting a first data voltage output from the output buffer to the output channel, and when the pixel is operated in the first mode, the outputting the data voltage to the second sub-pixel may include: outputting a ground voltage to the output channel.

When the pixel is operated in a second mode, the outputting the data voltage to the first sub-pixel may include: outputting the ground voltage to the output channel, and when the pixel is operated in the second mode, the outputting the data voltage to the second sub-pixel may include: outputting a second data voltage output from the output buffer to the output channel.

The outputting the data voltage to the first sub-pixel may further include: activating the output buffer in response to a source output enable signal at a turn-on level, and the outputting the data voltage to the second sub-pixel may further include: deactivating the output buffer in response to the source output enable signal at a turn-off level.

When the pixel is operated in a first mode, the outputting the data voltage to the first sub-pixel may include: connecting, by the multiplexer, the output buffer to the first data line in response to a first mux control signal at a turn-on level, and when the pixel is operated in the first mode, the outputting the data voltage to the second sub-pixel may include: connecting, by the multiplexer, a dummy voltage line to the second data line in response to a second dummy mux control signal at a turn-on level.

When the pixel is operated in a second mode, the outputting the data voltage to the first sub-pixel may include: connecting, by the multiplexer, the dummy voltage line to the first data line in response to a first dummy mux control signal at a turn-on level, and when the pixel is operated in the second mode, the outputting the data voltage to the second sub-pixel may include: connecting, by the multiplexer, the output buffer to the second data line in response to a second mux control signal at a turn-on level.

The outputting the data voltage to the first sub-pixel may further include: activating the data driver integrated circuit in response to a data driver enable signal at a turn-on level, and the outputting the data voltage to the second sub-pixel may further include: deactivating the data driver integrated circuit in response to the data driver enable signal at a turn-off level.

A display device and a method for driving the same according to the example embodiments may freely and easily vary a size and a shape of regions in which a privacy image and a share image are displayed.

A display device and a method for driving the same according to the example embodiments may reduce power consumption and delay deterioration of an element by deactivating the data driver integrated circuit or the output buffer when the dummy data voltage is provided to the sub-pixel.

A display device and a method for driving the same according to the example embodiments may reduce the number of the data driver integrated circuit and the lines and enable implementation of a thinned and miniaturized display device by connecting one output channel to a plurality of pixel units through a multiplexer.

A display device and a method for driving the same according to the example embodiments may implement the privacy mode and a share mode efficiently in various use environments.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with example embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and example embodiments of the present disclosure, and together with the description serve to explain principles and examples of the disclosure.

FIG. 1 is a block diagram of a display device according to an example embodiment.

FIG. 2 is a block diagram illustrating a configuration of a data driver integrated circuit according to an example embodiment.

FIG. 3 is a diagram illustrating a method for driving a display panel according to an example embodiment.

FIG. 4 is a diagram illustrating a configuration of a pixel according to an example embodiment.

FIG. 5 is an example illustrating an image displayed in a display panel.

FIG. 6 is a diagram illustrating a connection relationship between a pixel and a data driver integrated circuit according to a first example embodiment.

FIG. 7 is a waveform diagram of control and driving signals applied to a display device of FIG. 6.

FIG. 8 is a diagram illustrating a connection relationship between a pixel and a data driver integrated circuit according to a second example embodiment.

FIG. 9 is a waveform diagram of control and driving signals applied to a display device of FIG. 8.

FIG. 10 is a diagram illustrating a connection relationship between a pixel and a data driver integrated circuit according to a third example embodiment.

FIG. 11 is a waveform diagram of control and driving signals applied to a display device of FIG. 10.

FIG. 12 is a circuit diagram of a pixel according to an example embodiment.

FIG. 13 is a plan view illustrating a layout of a pixel illustrated in FIG. 12.

FIG. 14 is a plan view illustrating a unit pixel according to an example embodiment.

FIG. 15 is a view schematically illustrating a first lens illustrated in FIG. 14.

FIG. 16 is a view illustrating an optical profile with respect to a viewing angle of a first lens illustrated in FIG. 15.

FIG. 17 is a view schematically illustrating a second lens illustrated in FIG. 14.

FIG. 18 is a view illustrating an optical profile with respect to a viewing angle of a second lens illustrated in FIG. 17.

FIG. 19 is a schematic cross-sectional view of a display region of a display panel according to an example embodiment.

FIG. 20 is a view illustrating an example in which a display device according to an example embodiment is disposed.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, the example embodiments will be described with reference to the accompanying drawings. In this specification, when a component (or, an area, a layer, a part, etc.) is referred to as being “on,” “connected to” or “combined to” another component, the component may be directly on, connected to, or combined to the other component, or a third component therebetween may be present.

Like reference numerals refer to like elements throughout. Additionally, in the drawings, the thicknesses, proportions, and dimensions of components may be exaggerated for ease of description and clarity. The term “and/or” includes any and all combinations of one or more of the associated listed items.

It will be understood that when the terms “first,” “second,” “first-first,” “second-first,” “first-second,” “second-second,” and the like are used herein to describe various components, these components should not be limited by these terms. These terms are merely used to refer to one element separately from another. For example, a first component may be referred to as a second component and vice versa without departing from the scope of the present disclosure. Singular expressions and terms used herein also encompass or include plural expressions and terms, unless the context clearly indicates otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

In addition, terms such as “below,” “the lower side,” “on,” and “the upper side” are used to describe a relationship of configurations shown in the drawing. The terms are described as a relative concept based on a direction shown in the drawing.

In various embodiments of the present disclosure, the terms “include,” “comprise,” “including,” or “comprising,” may refer to a property, a fixed number, a step, a process, a component or combination thereof, but do not exclude other properties, fixed numbers, steps, processes, components, or combination thereof.

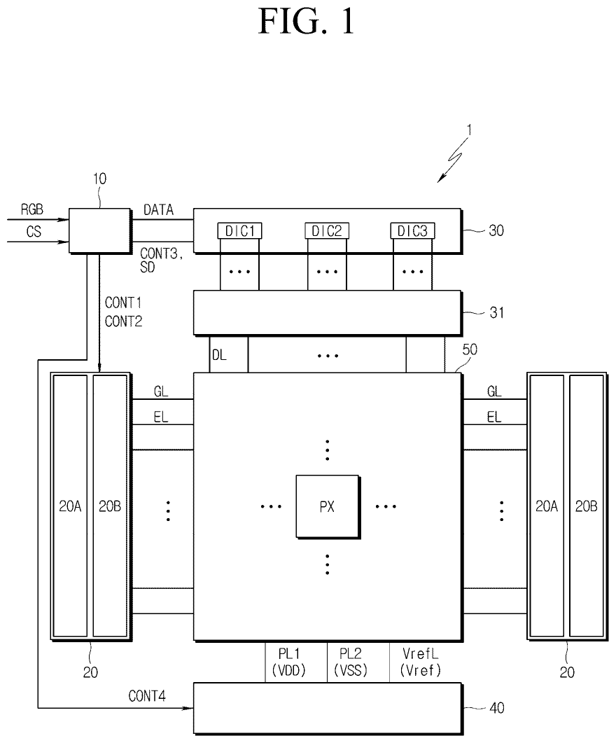

FIG. 1 is a block diagram of a display device according to an example embodiment.

Referring to FIG. 1, a display device 1 includes a timing controller 10, a gate driver 20, a data driver 30, a multiplexer 31 (or demultiplexer), a power supply unit 40, and a display panel 50.

The timing controller 10 may receive an image signal RGB and a control signal CS from an external host system, and the like. The image signal RGB may include a plurality of grayscale data. The control signal CS may include, for example, a horizontal synchronization signal, a vertical synchronization signal and a main clock signal.

The timing controller 10 processes the image signal RGB and the control signal CS to be suitable to operational conditions of the display panel 50, and may generate and output image data DATA, a gate driving control signal CONT1, an emission driving control signal CONT2, a data driving control signal CONT3, and a power supply control signal CONT4.

The gate driver 20 may include a scan driver 20A configured to generate scan signals based on the gate driving control signal CONT1 input from the timing controller 10. The scan driver 20A may provide the generated scan signals to the pixels PX through a plurality of scan lines GL. In an example embodiment, one pixel PX may be configured to receive a plurality of scan signals having different waveforms. In such an embodiment, the scan driver 20A may provide the plurality of scan signals to the pixels PX of a pixel row in correspondence therewith through the scan lines GL.

The gate driver 20 may further include a light emission driver 20B configured to generate light emission control signals based on the emission driving control signal CONT2 input from the timing controller 10. The light emission driver 20B may provide the generated light emission control signals to the pixels PX of the pixel row in correspondence therewith through light emission lines EL.

The gate driver 20 may be configured in a Gate-In-Panel form in which the gate driver 20 is mounted on the display panel 50. The gate driver 20 may be disposed on one side of the display panel 50, or on both sides (for example, left and right sides) of the display panel 50 as illustrated. According to a driving method, a panel design manner, and the like, the gate driver 20 may be disposed on both sides (for example, left and right sides) of the display panel 50, or may be connected to two or more side surfaces among four side surfaces of the display panel 50.

The data driver 30 may generate data signals based on the data driving control signal CONT3 and image data DATA output from the timing controller 10. The data driver 30 may provide the generated data signals to the pixels PX through a plurality of data lines DL.

The data driver 30 may include a plurality of data driver integrated circuits DIC1, DIC2 and DIC3. Each of the data driver integrated circuits DIC1, DIC2 and DIC3 may be connected to two or more data lines DL through a multiplexer 31 which will be described below. For example, when the number of the entire data lines DL is m, each of the data driver integrated circuits DIC1, DIC2 and DIC3 may be sequentially connected to m/3 data lines DL. Such data driver integrated circuits DIC1, DIC2 and DIC3 may be activated partially or as a whole based on a data driver enable signal SD applied from the timing controller 10. In FIG. 1, an example in which the data driver 30 includes three data driver integrated circuits DIC1, DIC2 and DIC3 is illustrated, however, the number thereof is not limited thereto, and a greater or a fewer number of data driver integrated circuits DIC1, DIC2 and DIC3 may be provided.

In an example embodiment, the display device 1 may include the multiplexer 31 connected between the data driver 30 and the pixels PX, and configured to time-dividedly drive the data lines DL. The multiplexer 31 connects each output channel of the data driver integrated circuits DIC1, DIC2 and DIC3 to two or more data lines DL. In addition, the multiplexer 31 may reduce a quantity of the output channels of the data driver integrated circuits DIC1, DIC2 and DIC3 by time-dividedly distributing a data voltage output from the output channels of the data driver integrated circuits DIC1, DIC2 and DIC3 to the data lines DL.

In an example embodiment, the multiplexer 31 may include a plurality of switching elements connected between the output channel of the data driver integrated circuits DIC1, DIC2 and DIC3 and the data lines DL. For example, the multiplexer 31 may be a 1:i multiplexer in which one output channel is connected to i (i is an integer greater than 1) data lines DL using one or more switching elements.

The power supply unit 40 may generate a high potential driving voltage VDD and a low potential driving voltage VSS to be provided to the display panel 50 based on the power supply control signal CONT4. The power supply unit 40 may provide the generated driving voltages VDD and VSS to the pixels PX through corresponding voltage lines PL1 and PL2. In addition, the power supply unit 40 may further generate a reference voltage Vref required for driving the pixel PX and provide it to the pixels PX through a corresponding voltage line VrefL.

The display panel 50 may include a plurality of pixels PX (or referred to as sub-pixels). The pixels PX may be disposed, for example, in a matrix form. The pixels PX disposed in one pixel row are connected to the same scan line GL and light emission line EL, and the pixels PX disposed in one pixel column are connected to the same data line DL. The pixels PX may emit light at luminance corresponding to a data signal and a scan signal supplied through the scan line GL and the data line DL in response to an emission control signal applied through the light emission line EL.

In an example embodiment, each pixel PX may display one color among red, green and blue. In another example embodiment, each pixel PX may display one color among cyan, magenta and yellow. In various example embodiments, each pixel PX may display one color among red, green, blue and white.

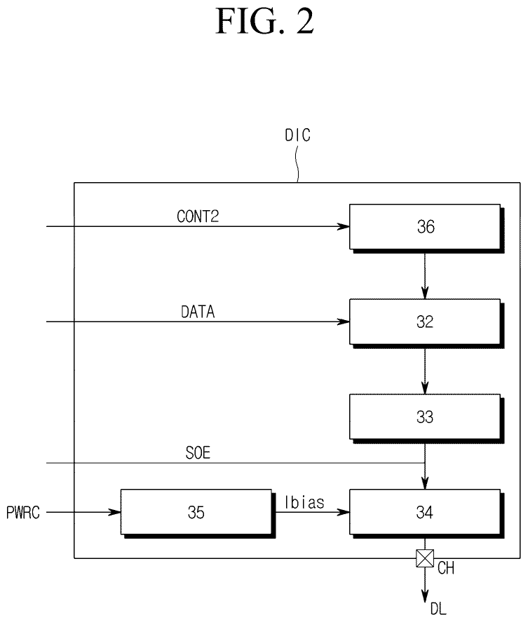

FIG. 2 is a block diagram illustrating a configuration of the data driver integrated circuit according to an example embodiment.

Referring to FIG. 2, the data driver integrated circuits DIC may include a register unit 36, a latch unit 32, a digital-to-analog converter (DAC) 33, and an output buffer 34.

The register unit 36 generates a sampling signal using a data driving control signal CONT3 received from the timing controller 10 (FIG. 1), and provides the generated sampling signal to the latch unit 32.

The latch unit 32 latches image data DATA received from the timing controller 10, and outputs the image data DATA to the DAC 33 in response to the sampling signal received from the register unit 36.

The DAC 33 may convert the image data DATA received from the latch unit 32 into a gamma compensation voltage to generate a data voltage.

The output buffer 34 outputs a data voltage output from the DAC 33 according to a source output enable signal SOE, received from the timing controller 10, to the data line DL through an output channel CH.

In an example embodiment, the data driver integrated circuit DIC may further include a power management circuit 35. The power management circuit 35 may generate a bias current Ibias based on a power control signal PWRC received from the timing controller 10, and apply the bias current Ibias to the output buffer 34. The power management circuit 35 may control a magnitude of the data voltage output from the data driver integrated circuit DIC and manage power consumption of the data driver integrated circuit DIC, by varying a magnitude of the bias current Ibias according to a mode instructed by the power control signal PWRC.

Meanwhile, the data driver integrated circuit DIC may include at least one or more output buffer 34. Each of the output buffers 34 may be connected to the data line DL in correspondence therewith through the output channel CH in correspondence therewith. In such an embodiment, consumed power of the data driver integrated circuit DIC may correspond to a sum of the consumed power of each of the output buffers 34.

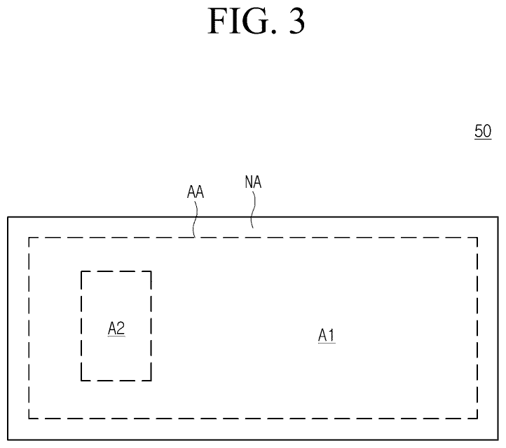

FIG. 3 is a diagram illustrating a method for driving the display panel according to an example embodiment.

Referring to FIG. 3, the display panel 50 may include a display region AA in which an image is displayed, and a non-display region NA around the display region AA. The display region AA may have generally a rectangular shape as illustrated, but is not limited thereto, and may be formed in a polygonal, circular, oval shape or a polygonal shape of which at least one edge is formed as a curve, etc. according to kinds of the display device 1 (FIG. 1). The non-display region NA may be disposed to surround the display region AA, and may be formed to follow a shape of the display region AA or to have an independent shape.

The display region AA may be divided into a first region A1 and a second region A2. The second region A2 is a region which displays a second image, for example, and may be driven to display a share image which is visible to all viewers. Here, the viewer may be, for example, a driver and a fellow passenger, and in such a case, the second region A2 may include a region disposed adjacent to a driver's seat, but is not limited thereto.

The first region A1 is a region which displays a first image different from the second image, for example, and may be driven to display a privacy image only visible to a certain viewer. Here, the viewer may be, for example, a fellow passenger, and in such a case, the first region A1 may include a region disposed adjacent to a front passenger's seat, but is not limited thereto.

The display panel 50 may be controlled such that the first region A1 operates in a first mode, and the second region A2 operates in a second mode. For example, the second region A2 may operate in the second mode having a wider viewing angle than that of the first region A1, and the first region A1 may operate in the first mode having a narrower viewing angle than that of the second region A2.

In other words, the second region A2 may operate in the second mode in which the viewing angle is expanded so that an image is visible to other viewer or all viewers, that is, a share mode, and the first region A1 may operate in the first mode in which the viewing angle is limited so that an image is visible to only a certain viewer (for example, a driver), that is, a privacy mode.

A position, a size and a shape of the first region A1 and the second region A2 is not limited. In an example embodiment, a position, a size and a shape of the first region A1 and the second region A2 may vary while the display panel 50 operates. For example, while the vehicle travels, a region adjacent to a front passenger's seat is allocated as the first region A1 and may operate in the privacy mode in which viewing with respect to the driver is limited, and while the vehicle does not travel, the region adjacent to the front passenger's seat may be allocated as the second region A2, and may operate in the share mode in which viewing with respect to the driver is permitted. In this case, while the vehicle does not travel, the second region A2 is changed into the entire region of the display panel 50.

Meanwhile, in the illustrated example embodiment, the second region A2 may have a smaller area than that of the first region A1. However, the example embodiment is not limited thereto.

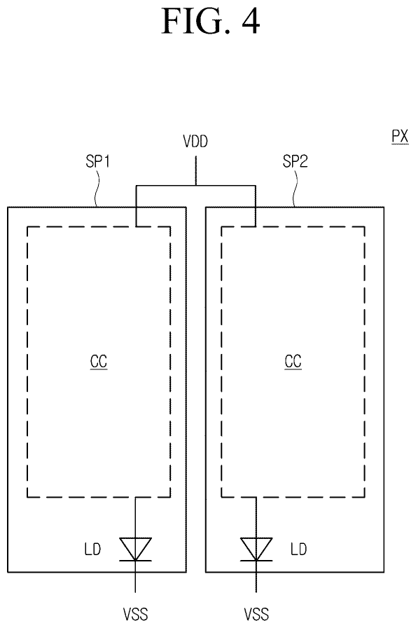

FIG. 4 is a diagram illustrating a configuration of the pixel according to an example embodiment.

Referring to FIG. 4, the pixel PX according to an example embodiment is configured to include a plurality of sub-pixels SP1 and SP2. For example, the pixel PX may be configured to include a first sub-pixel SP1 and a second sub-pixel SP2.

Each of the sub-pixels SP1 and SP2 may include a control circuit CC for controlling a light emitting diode LD and an amount of a drive current to be applied to the light emitting diode LD. The control circuit CC may include at least one transistor and a capacitor.

Control circuits CC of the sub-pixels SP1 and SP2 configuring one pixel PX may be configured with the same or different circuit. For example, the control circuits CC of the sub-pixels SP1 and SP2 may have the same circuit structure, and may be disposed to have a mirrored shape, but are not limited thereto.

The light emitting diode LD may display one color among red, green and blue. In another example embodiment, the light emitting diode LD may display one color among cyan, magenta and yellow. In another example embodiment, the light emitting diode LD may display one color among red, green, blue and white.

The light emitting diodes LD of the sub-pixels SP1 and SP2 configuring one pixel PX may display the same color. For example, the light emitting diodes LD of the sub-pixels SP1 and SP2 included in a red pixel PX may display a red color, the light emitting diodes LD of the sub-pixels SP1 and SP2 included in a green pixel PX may display a green color, and the light emitting diodes LD of the sub-pixels SP1 and SP2 included in a blue pixel PX may display a blue color.

Three pixels PX displaying red, green, and blue, respectively, may form one unit pixel. However, the present example embodiment is not limited thereto. As described above, when the pixels PX display cyan, magenta, and yellow, three pixels PX displaying cyan, magenta, and yellow, respectively, may form one unit pixel. Alternatively, when the pixels PX display red, green, blue, and white, four pixels PX displaying red, green, blue, and white, respectively, may form one unit pixel. Alternatively, two or more pixels PX displaying the same color may be included in one unit pixel.

In an example embodiment, the sub-pixels SP1 and SP2 included in one pixel PX may be driven to display different images. For example, the first sub-pixel SP1 may display the first image (the privacy image) described referring to FIG. 3, and the second sub-pixel SP2 may display the second image (the share image) described referring to FIG. 3. When the pixel PX is allocated to the first region A1 and driven in the first mode, the first sub-pixel SP1 may be driven to display the first image, and when the pixel PX is allocated to the second region A2 and driven in the second mode, the second sub-pixel SP2 may be driven to display the second image.

Meanwhile, when the pixel PX is driven in the first mode, the second sub-pixel SP2 may be driven to display a predetermined dummy image. The dummy image may be, for example, a black image, but is not limited thereto. On the contrary, when the pixel PX is driven in the second mode, the first sub-pixel SP1 may be driven to display a predetermined dummy image.

As described above, a position, a size and a shape of the first region A1 and the second region A2 may be varied. That is, while the display device 1 (FIG. 1) is driven, the pixel PX may operate in the first mode in a first period, and may operate in the second mode in a second period. In such an embodiment, in the first period, the first sub-pixel SP1 may display the first image, and the second sub-pixel SP2 may display a dummy image. In addition, in the second period, the second sub-pixel SP2 may display the second image and the first sub-pixel SP1 may display the dummy image.

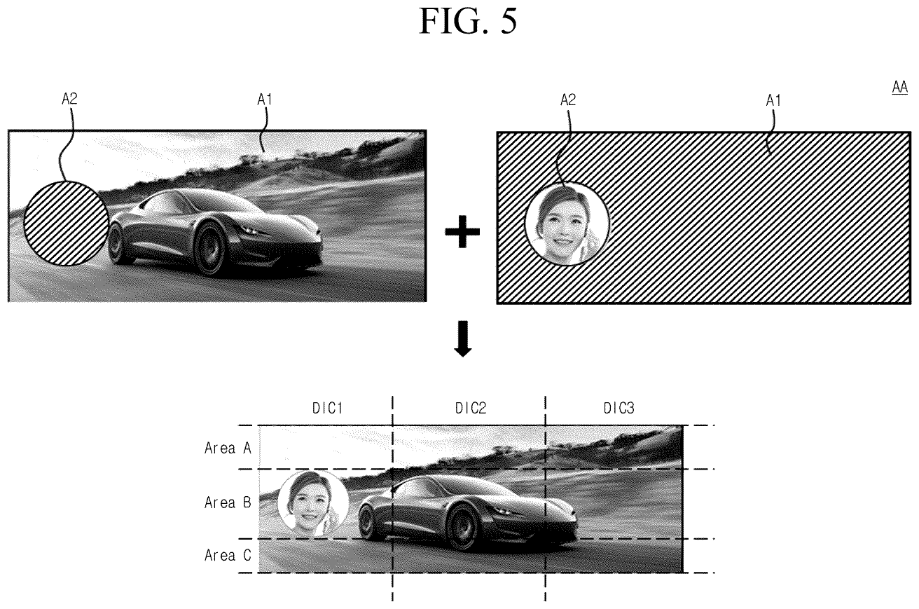

FIG. 5 is an example illustrating an image displayed in the display panel. In more detail, a left side in FIG. 5 illustrates an image displayed in the first sub-pixels SP1 (FIG. 4) configured to display the privacy image. A right side in FIG. 5 illustrates an image displayed in the second sub-pixels SP2 (FIG. 4) configured to display the share image. A lower side in FIG. 5 illustrates an entire image displayed in the display region AA through the first and second sub-pixels SP1 and SP2.

The display region AA may be divided into the first region A1 and the second region A2. The first region A1 is a region in which the first image which is the privacy image is displayed, and the second region A2 is a region in which the second image which is the share image is displayed. In the illustrated example embodiment, the second region A2 is disposed in a B region driven by the first data driver integrated circuit DIC1.

The first sub-pixels SP1 disposed in the first region A1 may display the privacy image in various gray scales, and the first sub-pixels SP1 disposed in the second region A2 may display a predetermined dummy image, for example, a black image. On the contrary, the second sub-pixels disposed in the first region A1 may display the black image, and the second sub-pixels SP2 disposed in the second region A2 may display the share image in various gray scales.

As illustrated, when an area of the second region A2 is set to be small, only some of the second sub-pixels SP2 display various gray scales, and most of the second sub-pixels SP2 display the dummy image. In such an embodiment, when all the data driver integrated circuits DIC1, DIC2 and DIC3 are activated for the second sub-pixel SP2 and configured to output the data voltage, unnecessary power consumption may be generated, and deterioration of the data driver integrated circuits DIC1, DIC2 and DIC3 may be accelerated.

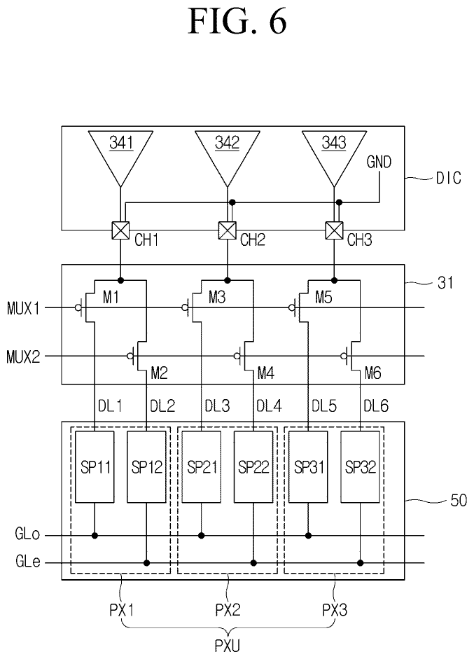

FIG. 6 is a diagram illustrating a connection relationship between the pixel and the data driver integrated circuit according to a first example embodiment.

Referring to FIG. 6, the data driver integrated circuit DIC may include a plurality of output channels CH1, CH2 and CH3 connected to the plurality of output buffers 341, 342 and 343, respectively. Each of the output channels CH1, CH2 and CH3 may output a data voltage applied from the output buffers 341, 342 and 343 connected thereto.

In an example embodiment, each of output channels CH1, CH2 and CH3 may be further connected to a ground voltage GND. In such an embodiment, the output channels CH1, CH2 and CH3 may be further controlled to output the ground voltage GND when the data voltage is not output from the plurality of output buffers 341, 342 and 343.

Each of the output channels CH1, CH2 and CH3 may be connected to the pixels PX1, PX2 and PX3 in correspondence therewith through the multiplexer 31. For example, the first output channel CH1 may be connected to the first pixel PX1, the second output channel CH2 may be connected to the second pixel PX2, and the third output channel CH3 may be connected to the third pixel PX3.

The multiplexer 31 includes a plurality of switching elements M1, M2, M3, M4, M5, and M6. Each of the switching elements M1, M2, M3, M4, M5, and M6 may be connected to one among the output channels CH1, CH2, and CH3 of the data driver integrated circuit DIC.

At this instance, two or more switching elements M1, M2, M3, M4, M5, and M6 may be connected to one output channel CH1, CH2, and CH3. For example, the first and second switching elements M1 and M2 may be connected to the first output channel CH1, the third and fourth switching elements M3 and M4 may be connected to the second output channel CH2, and the fifth and sixth switching elements M5 and M6 may be connected to the third output channel CH3.

Turning on and off of the switching elements M1, M2, M3, M4, M5, and M6 may be controlled through mux control signals MUX1 and MUX2 provided from the timing controller 10 (FIG. 1) and the like. For example, the first switching element M1, the third switching element M3, and the fifth switching element M5 are controlled according to a first mux control signal MUX1, and the second switching element M2, the fourth switching element M4, and the sixth switching element M6 may be controlled according to a second mux control signal MUX2. Here, because the switching elements M1, M2, M3, M4, M5, and M6 are controlled by two or more mux control signals MUX1 and MUX2, the multiplexer 31 may be referred to as a 2MUX structure.

The display panel 50 includes a plurality of pixels PX1, PX2, and PX3 disposed in a matrix form. In FIG. 6, the pixels PX1, PX2, and PX3, each of which displays a first color, a second color, and a third color, respectively, are illustrated representatively. Here, the first color may be red, the second color may be green, and the third color may be blue. However, the example embodiments are not limited thereto. The first to the third pixels PX1, PX2, and PX3 displaying the first to the third colors may configure one unit pixel PXU.

Each of the pixels PX1, PX2, and PX3 includes first and second sub-pixels SP11, SP12, SP21, SP22, SP31 and SP32. Each of the pixels SP11, SP12, SP21, SP22, SP31 and SP32 is driven to display the first image (the share image) or the second image (the privacy image) as described referring to FIG. 4.

The sub-pixels SP11, SP12, SP21, SP22, SP31 and SP32 may be connected to scan lines GL1 and GL2 and a light emission line (not illustrated). For example, the first sub-pixels SP11, SP21 and SP31 may be connected to a first scan line GLo, and the second sub-pixels SP12, SP22 and SP32 may be connected to a second scan line GLe. Here, the first scan line GLo may be an odd-numbered scan line and the second scan line GLe may be an even-numbered scan line.

The sub-pixels SP11, SP12, SP21, SP22, SP31 and SP32 may be further connected to the data lines DL1, DL2, DL3, DL4, DL5 and DL6 in correspondence with the sub-pixels SP11, SP12, SP21, SP22, SP31 and SP32. Each of the switching elements M1 to M6 of the multiplexer 31 may be connected to each input end of the data lines DL1, DL2, DL3, DL4, DL5 and DL6, respectively.

At this instance, the sub-pixels SP11, SP12, SP21, SP22, SP31, and SP32 configuring one pixel PX1, PX2, and PX3 may be connected to one output channel CH1, CH2, and CH3 through the switching elements M1, M2, M3, M4, M5, and M6. For example, the sub-pixels SP11 and SP12 configuring the first pixel PX1 may be connected to the first output channel CH1 through the first and second switching elements M1 and M2, the sub-pixels SP21 and SP22 configuring the second pixel PX2 may be connected to the second output channel CH2 through the third and fourth switching elements M3 and M4, and the sub-pixels SP31 and SP32 configuring the third pixel PX3 may be connected to the third output channel CH3 through the fifth and sixth switching elements M5 and M6.

When the switching elements M1, M2, M3, M4, M5, and M6 are turned on according to the mux control signal MUX1 and MUX2, a data voltage may be applied to the data lines DL1, DL2, DL3, DL4, DL5, and DL6 connected to the corresponding switching elements M1, M2, M3, M4, M5, and M6. In more detail, when the first, third, and fifth switching elements M1, M3, and M5 are turned on by the first mux control signal MUX1, a data voltage may be applied to the first sub-pixels SP11, SP21, and SP31 of each pixel PX1, PX2, and PX3 connected to the first, third, and fifth data lines DL1, DL3, and DL5. In addition, when the second, fourth, and sixth switching elements M2, M4, and M6 are turned on by the second mux control signal MUX2, a data voltage may be applied to the second sub-pixels SP12, SP22, and SP32 of each pixel PX1, PX2, and PX3 connected to the second, fourth, and sixth data lines DL2, DL4, and DL6.

In an example embodiment, the switching elements M1, M2, M3, M4, M5, and M6 may be configured as a transistor. In an illustrated example embodiment, the switching elements M1, M2, M3, M4, M5, and M6 are pmos transistors. In such an embodiment, a turn-on level of the mux control signals MUX1 and MUX2 may have a low level. However, in another example embodiment, the switching elements M1, M2, M3, M4, M5, and M6 may be nmos transistors. In such an embodiment, a turn-on level of the mux control signal MUX1 and MUX2 may be a high level.

In an example embodiment, the output buffers 341, 342, and 343 may output a data voltage corresponding to the first image in synchronization with the first mux control signal MUX1 in a turn-on level, and may output a data voltage corresponding to the second image in synchronization with the second mux control signal MUX2 in a turn-on level. Then, while the first mux control signal MUX1 is applied, a data voltage corresponding to the first image may be applied to the first sub-pixels SP11, SP21 and SP31, and while the second mux control signal MUX2 is applied, a data voltage corresponding to the second image may be applied to the second sub-pixels SP12, SP22 and SP32. Therefore, the first sub-pixels SP11, SP21 and SP31 may emit light at luminance corresponding to the first image, and the second sub-pixels SP12, SP22 and SP32 may emit light at luminance corresponding to the second image.

If the first image to be displayed in the first sub-pixels SP11, SP21 and SP31 does not exist in a certain frame (for example, the pixels PX1, PX2 and PX3 operate in the second mode in the corresponding frame), the output buffers 341, 342 and 343 (or the data driver integrated circuit DIC in which the output buffers 341, 342 and 343 are included) may be controlled to be deactivated in the first period t1. Instead, the ground voltage GND may be output through the output channels CH1, CH2 and CH3.

On the contrary, if the second image to be displayed in the second sub-pixels SP12, SP22 and SP32 does not exist in a certain frame (for example, the pixels PX1, PX2 and PX3 operate in the first mode in the corresponding frame), the output buffers 341, 342 and 343 may be deactivated in the second period t2, and the ground voltage GND may be output through the output channels CH1, CH2 and CH3. Here, the ground voltage GND may be a voltage in correspondence with the black image, that is, a black gray scale.

In the example embodiment described above, the output channels CH1, CH2, and CH3 of the data driver integrated circuit DIC and the sub-pixels SP11, SP12, SP21, SP22, SP31, and SP32 have a connection relationship of 1:n, that is, 1:2. That is, one output channel CH1, CH2, and CH3 is connected to the first sub-pixel SP11, SP21, and SP31 and the second sub-pixel SP12, SP22, and SP32 configuring one pixel PX1, PX2, and PX3 in a 1:n relationship through the multiplexer 31. However, the example embodiment is not limited thereto. In various example embodiments, one output channel CH1, CH2 and CH3 may be connected to three or more sub-pixels disposed in two or more pixels through the multiplexer 31.

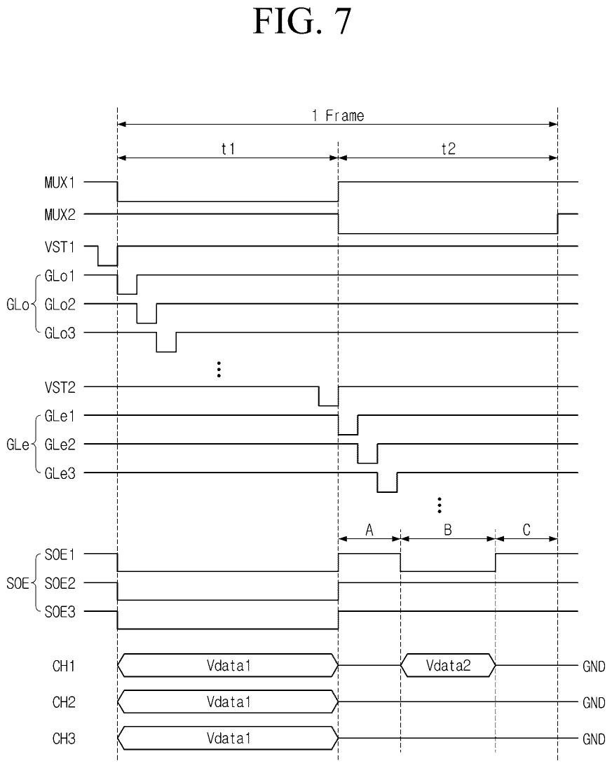

FIG. 7 is a waveform diagram of control and driving signals applied to the display device of FIG. 6. In more detail, FIG. 7 shows the control and driving signals applied so as to display an image illustrated in FIG. 5.

Referring to FIGS. 5 to 7 together, the display device 1 (FIG. 1) may be driven on a frame basis. One frame may be time-divided into the first period t1 and the second period t2.

In the first period t1, a first data voltage Vdata1 may be applied to the first sub-pixels SP11, SP21 and SP31 for displaying the first image (the privacy image), and in the second period t2, a second data voltage Vdata2 may be applied to the second sub-pixels SP12, SP22 and SP32 for displaying the second image (the share image).

In more detail, in the first period t1, a scan signal at a turn-on level may be sequentially applied to the first scan lines GLo in response to a first gate start signal VST1. In addition, in the second period t2, the scan signal at a turn-on level may be applied to the second scan lines GLe in response to a second gate start signal VST2.

The data driver integrated circuits DIC1, DIC2 and DIC3 may be activated based on the data driver enable signals SD1, SD2 and SD3. The output buffers 341, 342 and 343 inside each of the data driver integrated circuits DIC1, DIC2 and DIC3 may output a data voltage with respect to the sub-pixels SP11, SP12, SP21, SP22, SP31 and SP32 in synchronization with the scan signals.

For example, each of the output buffers 341, 342 and 343 may output the first data voltage Vdata1 which will be applied to the first sub-pixels SP11, SP21 and SP31 in the first period t1, and may output the second data voltage Vdata2 which will be applied to the second sub-pixels SP12, SP22 and SP32 in the second period t2.

The timing controller 10 (FIG. 1) may time-divide one frame, and provide the mux control signals MUX1 and MUX2 sequentially in the time-divided periods t1 and t2, thereby sequentially turning on the switching elements M1 to M6 of the multiplexer 31.

In the first period t1, the first mux control signal MUX1 in a turn-on level is applied to the multiplexer 31. Then, the first, third, and fifth switching elements M1, M3, and M5 are turned on, and the first data voltage Vdata1 output from the output buffers 341, 342, and 343 may be applied to the first sub-pixels SP11, SP21, and SP31.

In the second period t2, the second mux control signal MUX2 in a turn-on level is applied to the multiplexer 31. Then, the second, fourth, and sixth switching elements M2, M4, and M6 are turned on, and the second data voltage Vdata2 output from the output buffers 341, 342, and 343 may be applied to the second sub-pixels SP12, SP22, and SP32.

In such a manner, as the image data in the first mode or the second mode is applied with respect to the pixels PX, the size, and the shape of the first region A1 (FIG. 3) in which the first image is displayed and the second region A2 (FIG. 3) in which the second image is displayed in the display panel 50 may be freely changed.

According to a driving mode, at least some of the sub-pixels SP11, SP12, SP21, SP22, SP31 and SP32 may display the dummy image. For example, in an example embodiment illustrated in FIG. 5, most of the second sub-pixels SP12, SP22 and SP32 may be configured to display the dummy image. In such an embodiment, when controlling to activate all the data driver integrated circuits DIC1, DIC2 and DIC3 in the entire frame period, and to output a predetermined second data voltage Vdata2 to the second sub-pixels SP12, SP22 and SP32, unnecessary power consumption may be generated. To prevent the above, while the dummy image is displayed, the output buffers 341, 342 and 343 connected to the second sub-pixels SP12, SP22 and SP32 may be deactivated.

For example, in the second period t2, the second sub-pixels SP12, SP22 and SP32 disposed in the A region may display the dummy image. That is, the controlled second data voltage Vdata2 need not be provided to the second sub-pixels SP12, SP22 and SP32 disposed in the A region.

Therefore, while the scan signal is applied to the second sub-pixels SP12, SP22 and SP32 disposed in the A region, the output buffers 342, 342 and 343 in all the data driver integrated circuits DIC1, DIC2 and DIC3 may be deactivated. For example, the source output enable signal SOE in a turn-off level (for example, a high level) may be applied to all the data driver integrated circuits DIC1, DIC2 and DIC3 from the timing controller 10. Therefore, the second data voltage Vdata2 may not be output from the output buffers 341, 342 and 343.

Instead, the ground voltage GND connected to each of the output channels CH1, CH2 and CH3 may be provided to the data lines DL1 to DL6. Then, the dummy data voltage, for example, the ground voltage GND may be applied to the second sub-pixels SP12, SP22 and SP32 disposed in the A region, and a predetermined dummy image in correspondence with the ground voltage GND may be displayed.

As the second data voltage Vdata2 is not output from the output buffers 341, 342 and 343, power consumption of the data driver integrated circuits DIC1, DIC2 and DIC3 may be reduced. In addition, while the operation of the data driver integrated circuits DIC1, DIC2 and DIC3 is idle, the circuit element may be regenerated, and a speed of deterioration may decrease.

While the output buffers 341, 342 and 343 are deactivated, the image data DATA (FIG. 1) may not be applied to the data driver integrated circuits DIC1, DIC2 and DIC3 from the timing controller 10 (FIG. 1). With this configuration, power consumption of the data driver integrated circuits DIC1, DIC2 and DIC3 may further decrease.

In the second period t2, the second sub-pixels SP12, SP22 and SP32 connected to the first data driver integrated circuit DIC1 among the second sub-pixels SP12, SP22 and SP32 disposed in the B region may display a predetermined gray scale according to the second image. That is, a predetermined controlled second data voltage Vdata2 has to be provided to the second sub-pixels SP12, SP22 and SP32 through the first data driver integrated circuit DIC1.

Therefore, while the scan signal is applied to the second sub-pixels SP12, SP22 and SP32 disposed in the B region, the output buffers 341, 342 and 343 disposed in the first data driver integrated circuit DIC1 may be activated. For example, the first source output enable signal SOE1 in a turn-on level (for example, a low level) may be applied to the first data driver integrated circuit DIC1 from the timing controller 10 (FIG. 1).

The timing controller 10 provides the image data DATA to the activated first data driver integrated circuit DIC1, and the first data driver integrated circuit DIC1 converts the image data DATA, thereby generating the second data voltage Vdata2. The second data voltage Vdata2 may be provided to the second sub-pixels SP12, SP22 and SP32 through the output buffers 341, 342 and 343.

Meanwhile, while the first data driver integrated circuit DIC1 is activated, the output buffers 341, 342 and 343 in the second and third data driver integrated circuits DIC2 and DIC3 connected to the second sub-pixels SP12, SP22 and SP32 displaying the dummy image may be controlled to still be in the deactivated state.

In the second period t2, the second sub-pixels SP12, SP22 and SP32 disposed in the C region display the dummy image. That is, the controlled second data voltage Vdata2 need not be provided to the second sub-pixels SP12, SP22 and SP32 disposed in the A region. Therefore, while the scan signal is applied to the second sub-pixels SP12, SP22 and SP32 disposed in the C region, the output buffers 341, 342 and 343 in all the data driver integrated circuits DIC1, DIC2 and DIC3 may be deactivated.

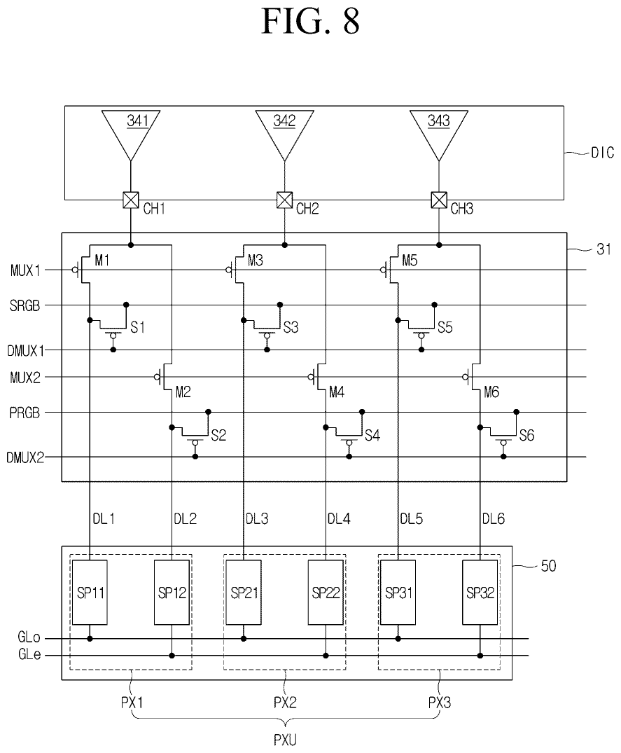

FIG. 8 is a diagram illustrating a connection relationship between the pixel and the data driver integrated circuit according to a second example embodiment.

Compared to the example embodiment in FIG. 6, the multiplexer 31 according to an example embodiment may further include a plurality of dummy switching elements S1 to S6.

Each of the dummy switching elements S1 to S6 may be connected to one among the data lines DL1 to DL6, respectively. For example, a first dummy switching element S1 may be connected to a first data line DL1, a second dummy switching element S2 may be connected to a second data line DL2, a third dummy switching element S3 may be connected to a third data line DL3, a fourth dummy switching element S4 may be connected to a fourth data line DL4, a fifth dummy switching element S5 may be connected to a fifth data line DL5, and a sixth dummy switching element S6 may be connected to a sixth data line DL6.

Turning on and off of the dummy switching elements S1 to S6 may be controlled through dummy mux control signals DMUX1 and DMUX2 provided from the timing controller 10 (FIG. 1). For example, first, third and fifth dummy switching elements S1, S3 and S5 may be controlled according to a first dummy mux control signal DMUX1, and second, fourth and sixth dummy switching elements S2, S4 and S6 may be controlled according to a second dummy mux control signal DMUX2.

Each of the dummy switching elements S1 to S6 may be further connected to dummy voltage lines SRGB and PRGB. The dummy voltage lines SRGB and PRGB may receive a predetermined dummy data voltage, for example, a black gray scale voltage from the power supply unit 40 (FIG. 1) and the like. The black gray scale voltage may be, for example, a DC voltage of 0V, but is not limited thereto.

When the dummy switching elements S1 to S6 are turned on according to the dummy mux control signals DMUX1 and DMUX2, the data lines DL1 to DL6 connected to the corresponding dummy switching elements S1 to S6 may be electrically connected to the dummy voltage lines SRGB and PRGB. Accordingly, the black gray scale voltage may be applied to the data lines DL1 to DL6.

In more detail, when the first, third and fifth dummy switching elements S1, S3 and S5 are turned on by the first dummy mux control signal DMUX1, the black gray scale voltage may be applied to the first sub-pixels SP11, SP21 and SP31 of the pixels PX1, PX2 and PX3 connected to the first, third and fifth data lines DL1, DL3 and DL5. In addition, when the second, fourth, and sixth dummy switching elements S2, S4 and S6 are turned on by the second dummy mux control signal DMUX2, the black gray scale voltage may be applied to the second sub-pixels SP12, SP22 and SP32 of the pixels PX1, PX2 and PX3 connected to the second, fourth and sixth data lines DL2, DL4 and DL6.

In an example embodiment, the dummy switching elements S1 to S6 may be formed of the transistors. In the illustrated example embodiment, the dummy switching elements S1 to S6 are pmos transistors. In such an embodiment, a turn-on level of the dummy mux control signals DMUX1 and DMUX2 may be a low level. However, in another example embodiment, the dummy switching elements S1 to S6 may be nmos transistors. In such an embodiment, a turn-on level of the dummy mux control signals DMUX1 and DMUX2 may be a high level.

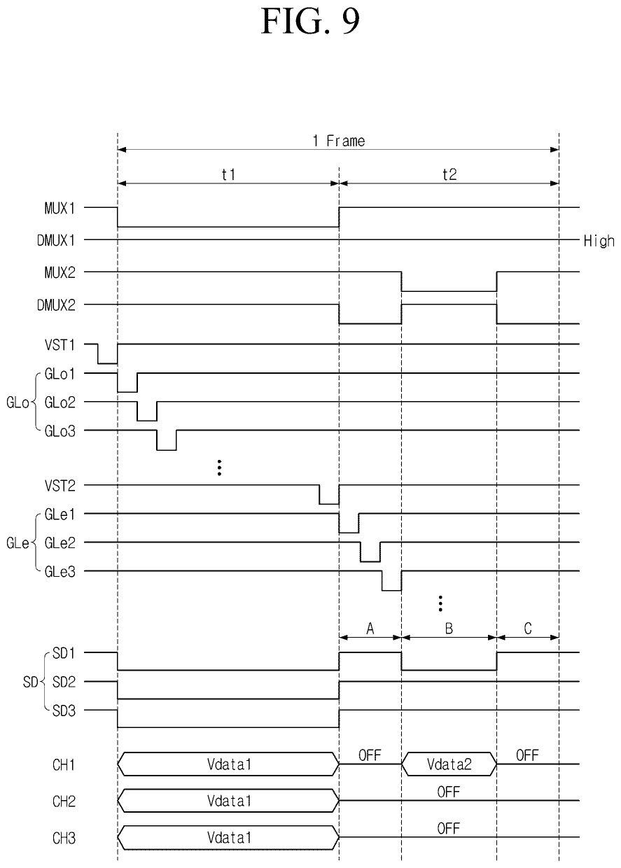

FIG. 9 is a waveform diagram of control and driving signals applied to the display device of FIG. 8. In more detail, FIG. 9 shows the control and driving signals applied so as to display an image illustrated in FIG. 5.

Referring to FIGS. 5, 8 and 9 together, the display device 1 (FIG. 1) may be driven on a frame basis. One frame may be time-divided into the first period t1 and the second period t2.

In the first period t1, a first data voltage Vdata1 may be applied to the first sub-pixels SP11, SP21 and SP31 for displaying the first image (the privacy image), and in the second period t2, a second data voltage Vdata2 may be applied to the second sub-pixels SP12, SP22 and SP32 for displaying the second image (the share image).

According to a driving mode, at least some of the sub-pixels SP11, SP12, SP21, SP22, SP31 and SP32 may display the dummy image. For example, in an example embodiment illustrated in FIG. 5, most of the second sub-pixels SP12, SP22 and SP32 may be configured to display the dummy image. In such an embodiment, when controlling to activate all the data driver integrated circuits DIC1, DIC2 and DIC3 in the entire frame period, and to output a predetermined second data voltage Vdata2 to the second sub-pixels SP12, SP22 and SP32, unnecessary power consumption may be generated. To prevent the above, while the dummy image is displayed, the data driver integrated circuits DIC1, DIC2 and DIC3 connected to the second sub-pixels SP12, SP22 and SP32 may be deactivated.

For example, in the second period t2, the second sub-pixels SP12, SP22 and SP32 disposed in the A region may display the dummy image. That is, the controlled second data voltage Vdata2 need not be provided to the second sub-pixels SP12, SP22 and SP32 disposed in the A region.

Therefore, while the scan signal is applied to the second sub-pixels SP12, SP22 and SP32 disposed in the A region, all the data driver integrated circuits DIC1, DIC2 and DIC3 may be deactivated. For example, the data driver enable signals SD1, SD2 and SD3 in a turn-off level (for example, a high level) may be applied to all the data driver integrated circuits DIC1, DIC2 and DIC3 from the timing controller 10 (FIG. 1). Therefore, the second data voltage Vdata2 may not be output from all the data driver integrated circuits DIC1, DIC2 and DIC3. In addition, the second mux control signal MUX2 in a turn-off level may be applied and this may prevent an unnecessary voltage from being output from the deactivated data driver integrated circuits DIC1, DIC2 and DIC3 to the data lines DL2, DL4 and DL6.

Instead, the second dummy mux control signal DMUX2 in a turn-on level (for example, a low level) may be applied from the timing controller 10. Then, the second, fourth, and sixth dummy switching elements S2, S4 and S6 may be turned on, and the second dummy voltage line PRGB and the second, fourth and sixth data lines DL2, DL4 and DL6 may be electrically connected. The black gray scale voltage applied to the second dummy voltage line PRGB may be applied to the second sub-pixels SP12, SP22 and SP32 through the second, fourth and sixth data lines DL2, DL4 and DL6. Then, the dummy image in correspondence with the black gray scale may be displayed in the second sub-pixels SP12, SP22 and SP32 disposed in the A region.

As the data driver integrated circuits DIC1, DIC2 and DIC3 are deactivated, power consumption of the data driver integrated circuits DIC1, DIC2 and DIC3 may be reduced. In addition, while the operation of the data driver integrated circuits DIC1, DIC2 and DIC3 is idle, the circuit element may be regenerated, and a speed of deterioration may decrease.

While the data driver integrated circuits DIC1, DIC2 and DIC3 are deactivated, the image data DATA (FIG. 1) may not be applied to the data driver integrated circuits DIC1, DIC2 and DIC3 from the timing controller 10. With this configuration, power consumption of the display device 1 may further decrease.

In the second period t2, the second sub-pixels SP12, SP22 and SP32 connected to the first data driver integrated circuit DIC1 among the second sub-pixels SP12, SP22 and SP32 disposed in the B region may display a predetermined gray scale according to the second image. That is, a predetermined controlled second data voltage Vdata2 has to be provided to the second sub-pixels SP12, SP22 and SP32 through the first data driver integrated circuit DIC1.

Therefore, while the scan signal is applied to the second sub-pixels SP12, SP22 and SP32 disposed in the B region, the first data driver integrated circuit DIC1 may be activated. For example, the first data driver enable signal SD1 in a turn-on level (for example, a low level) may be applied to the first data driver integrated circuit DIC1 from the timing controller 10.

The timing controller 10 provides the image data DATA to the activated first data driver integrated circuit DIC1, and the first data driver integrated circuit DIC1 converts the image data DATA, thereby generating the second data voltage Vdata2. The second data voltage Vdata2 may be provided to the second sub-pixels SP12, SP22 and SP32 through the output buffers 341, 342 and 343. The second mux control signal MUX2 in a turn-on level may be applied so that the second data voltage Vdata2 output from the first data driver integrated circuit DIC1 can be provided to the data lines DL2, DL4 and DL6.

Meanwhile, while the first data driver integrated circuit DIC1 is activated, the second and third data driver integrated circuits DIC2 and DIC3 connected to the second sub-pixels SP12, SP22 and SP32 displaying the dummy image may be controlled to still be in the deactivated state.

In the second period t2, the second sub-pixels SP12, SP22 and SP32 disposed in the C region display the dummy image. That is, the controlled second data voltage Vdata2 need not be provided to the second sub-pixels SP12, SP22 and SP32 disposed in the A region. Therefore, while the scan signal is applied to the second sub-pixels SP12, SP22 and SP32 disposed in the C region, all the data driver integrated circuits DIC1, DIC2 and DIC3 may be deactivated.

Meanwhile, the method for reducing the power consumption while an image in the second region A2 is displayed is described above, however, the example embodiment described above may be applied the same to a case in which an image in the first region A1 is displayed.

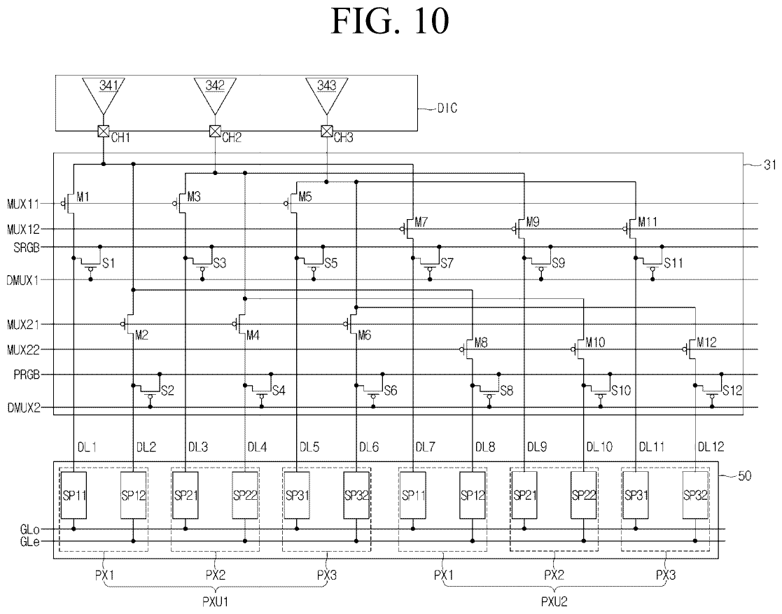

FIG. 10 is a diagram illustrating a connection relationship between the pixel and the data driver integrated circuit according to a third example embodiment.

In comparison with the example embodiment in FIG. 8, in the example embodiment in FIG. 10, each of the output channels CH1, CH2 and CH3 may be connected to the pixels PX1, PX2 and PX3 of the plurality of unit pixels PXU1 and PXU2 through the multiplexer 31. For example, the first output channel CH1 may be connected to the first pixels PX1 of the first and second unit pixels PXU1 and PXU2, the second output channel CH2 may be connected to the second pixels PX2 of the first and second unit pixels PXU1 and PXU2, and the third output channel CH3 may be connected to the third pixels PX3 of the first and second unit pixels PXU1 and PXU2. As such, when one output channel CH1, CH2 and CH3 is connected to the plurality of unit pixels PXU1 and PXU2, the number of the data driver integrated circuit DIC and the number of lines configuring the data driver 30 (FIG. 1) decrease, and a miniaturized display device 1 (FIG. 1) may be implemented.

The multiplexer 31 may include a plurality of switching elements M1 to M12. Each of the switching elements M1 to M12 may be connected to one among the output channels CH1, CH2 and CH3 of the data driver 30. At this instance, two or more switching elements M1 to M12 may be connected to one output channel CH1, CH2 and CH3. Turning on and off of the switching elements M1 to M12 may be controlled through the mux control signals MUX11, MUX12, MUX21 and MUX22 provided from the timing controller 10 (FIG. 1) and the like.

The display panel 50 includes a plurality of pixels PX1 and PX2 disposed in a matrix form. Each of the unit pixels PXU1 and PXU2 includes a plurality of pixels PX1, PX2 and PX3. Each of the pixels PX1, PX2 and PX3 configuring one unit pixel PXU1 and PXU2 includes first and second sub-pixels SP11, SP12, SP21, SP22, SP31, and SP32.

The sub-pixels SP11, SP12, SP21, SP22, SP31 and SP32 may be connected to the data lines DL1 to DL12 in correspondence therewith. The switching elements M1 to M12 of the multiplexer 31 may be connected to input ends of the data lines DL1 to DL12, respectively.

At this instance, each of the sub-pixels SP11, SP12, SP21, SP22, SP31 and SP32 included in the plurality of unit pixels PXU1 and PXU2 may be connected to one output channel CH1, CH2 and CH3 through the switching elements M1 to M12. For example, the first sub-pixels SP11 configuring the first pixel PX1 of the unit pixels PXU1 and PXU2 may be connected to the first output channel CH1 through the first and seventh switching elements M1 and M7, and the second sub-pixels SP12 thereof may be connected to the first output channel CH1 through the second and eighth switching elements M2 and M8.

The first sub-pixels SP21 configuring the second pixel PX2 of the unit pixels PXU1 and PXU2 may be connected to the second output channel CH2 through the third and ninth switching elements M3 and M9, and the second sub-pixels SP22 thereof may be connected to the second output channel CH2 through the fourth and tenth switching elements M4 and M10. The first sub-pixels SP31 configuring the third pixel PX3 of the unit pixels PXU and PXU2 may be connected to the third output channel CH3 through the fifth and eleventh switching elements M5 and M11, and the second sub-pixels SP32 thereof may be connected to the third output channel CH3 through the sixth and twelfth switching elements M6 and M12.

The multiplexer 31 may further include a plurality of dummy switching elements S1 to S12. The dummy switching elements S1 to S12 may be connected to one among the data lines DL1 to DL12, respectively. The dummy switching elements S1 to S12 may be further connected to the dummy voltage lines SRGB and PRGB. The dummy voltage lines SRGB and PRGB may receive a voltage corresponding to a predetermined dummy data voltage, for example, a black gray scale voltage from the power supply unit 40 (FIG. 1) and the like. The black gray scale voltage may be, for example, a DC voltage of 0V, but is not limited thereto.

Turning on and off of the dummy switching elements S1 to S12 may be controlled through the dummy mux control signals DMUX1 and DMXU2 provided from the timing controller 10 (FIG. 1) and the like. When the dummy switching elements S1 to S12 are turned on according to the dummy mux control signals DMUX1 and DMUX2, the data lines DL1 to DL12 connected to the corresponding dummy switching elements S1 to S12 may be electrically connected to the dummy voltage lines SRGB and PRGB. Accordingly, the black gray scale voltage may be applied to the data lines DL1 to DL12.

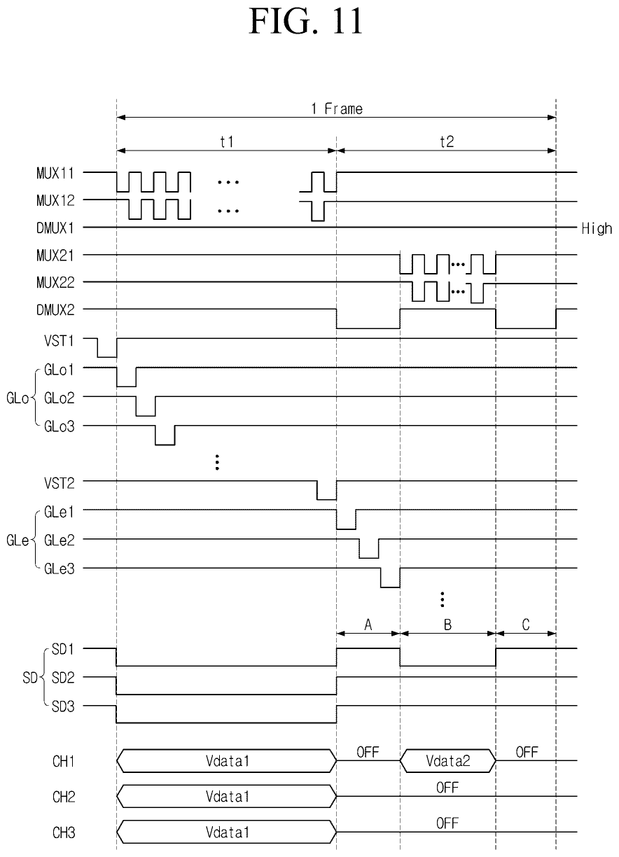

FIG. 11 is a waveform diagram of control and driving signals applied to the display device of FIG. 10. In more detail, FIG. 11 shows the control and driving signals applied so as to display an image illustrated in FIG. 5.

Referring to FIGS. 5, 10 and 11 together, the display device 1 (FIG. 1) may be driven on a frame basis. One frame may be time-divided into the first period t1 and the second period t2.

In the first period t1, the first data voltage Vdata1 may be applied to the first sub-pixels SP11, SP21 and SP31 for displaying the first image (the privacy image), and in the second period t2, the second data voltage Vdata2 may be applied to the second sub-pixels SP12, SP22 and SP32 for displaying the second image (the share image).

In more detail, in the first period t1, the scan signal at a turn-on level may be sequentially applied to the first scan lines GLo in response to the first gate start signal VST1. In addition, in the second period t2, the scan signal at a turn-on level may be sequentially applied to the second scan lines GLe in response to the second gate start signal VST2. Each of the scan signals may be applied in a turn-on level in one horizontal period 1H.

The timing controller 10 (FIG. 1) may time-divide one frame, and sequentially provide the mux control signals MUX11, MUX12, MUX21 and MUX22 to the time-divided periods t1 and t2, thereby turning on the switching elements M1 to M12 of the multiplexer 31 sequentially.

The first mux control signal MUX11 and MUX12 in a turn-on level may be applied to the multiplexer 31 in the first period t1. Here, a (1-1)th mux control signal MUX11 and a (1-2)th mux control signal MUX12 may be sequentially applied by time-dividing one horizontal period 1H. The first data voltage Vdata1 output from the output buffers 341, 342 and 343 may be applied to the first sub-pixels SP11, SP21 and SP31 included in the plurality of unit pixels PXU1 and PXU2 in response to the first mux control signals MUX11 and MUX12 which are sequentially turned on.

Likewise, the second mux control signals MUX21 and MUX22 in a turn-on level may be applied to the multiplexer 31 in the second period t2. Here, a (2-1)th mux control signal MUX21 and a (2-2)th mux control signal MUX22 may be sequentially applied by time-dividing the one horizontal period 1H. The second data voltage Vdata2 output from the output buffers 341, 342 and 343 may be applied to the second sub-pixels SP12, SP22 and SP32 included in the plurality of unit pixels PXU1 and PXU2 in response to the second mux control signals MUX21 and MUX22 which are sequentially turned on.

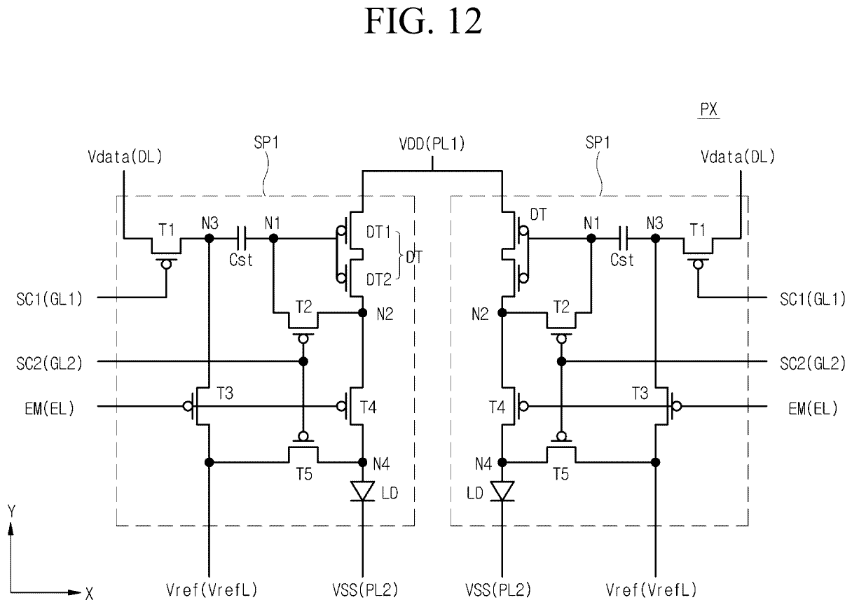

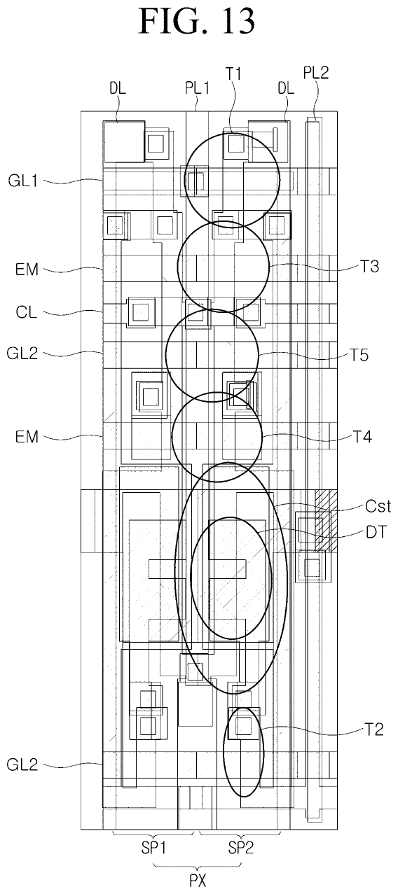

FIG. 12 is a circuit diagram of the pixel according to an example embodiment. FIG. 13 is a plan view illustrating a layout of the pixel illustrated in FIG. 12.

Referring to FIGS. 12 and 13 together, the display panel 50 may include a first scan line GL1, a second scan line GL2, and the light emission line EL extending in a row direction, and may include a high potential driving voltage line PL1, a low potential driving voltage line PL2, the data line DL and a reference voltage line VrefL extending in a column direction generally perpendicular to the row direction. One sub-pixel SP1 and SP2 may be formed in a region in which the first scan line GL1, the second scan line GL2, the light emission line EL, the high potential driving voltage line PL1, the low potential driving voltage line PL2, and the data line DL intersect one another.

Two sub-pixels SP1 and SP2 adjacent to each other in the row direction may form one pixel PX. The sub-pixels SP1 and SP2 forming one pixel PX may be formed as the same or different circuits. When the sub-pixels SP1 and SP2 forming one pixel PX is formed as the same circuit, the sub-pixels SP1 and SP2 may have a layout in which the sub-pixels SP1 and SP2 are mirrored to each other based on the column direction. In more detail, two sub-pixels SP1 and SP2 adjacent to each other and forming one pixel PX may have a layout mirrored to each other based on the high potential driving voltage line PL1. However, the present example embodiment is not limited thereto.

In an example embodiment, the two sub-pixels SP1 and SP2 adjacent to each other may share at least one among the high potential driving voltage line PL1, the low potential driving voltage line PL2, the data line DL and the reference voltage line VrefL. For example, two sub-pixels SP1 and SP2 included in one pixel PX may share one high potential driving voltage line PL1. In addition, for example, two or more pixels PS may share the low potential driving voltage line PL2 and/or the reference voltage line VrefL. At this instance, in order to connect the reference voltage line VrefL extending in the column direction to the sub-pixels SP1 and SP2, a connection line CL extending in the row direction may be formed by passing through the sub-pixels SP1 and SP2. However, the present example embodiment is not limited thereto.

Hereinafter, a configuration of the sub-pixels SP1 and SP2 will be described based on the first sub-pixel SP1.

The first sub-pixel SP1 according to an example embodiment may include a driving transistor DT, the light emitting diode LD connected to the driving transistor DT, and a control circuit configured to control an amount of a driving current which will be applied to the driving transistor DT through the driving transistor DT. For example, the control circuit may include first to fifth transistors T1 to T5 and a capacitor Cst. In such an embodiment, one pixel PX may have a 12T2C structure.

A first electrode of the driving transistor DT is configured to receive the high potential driving voltage VDD (connected to a high potential driving voltage line PL1), and a second electrode thereof is connected to a second node N2. A gate electrode of the driving transistor DT is connected to the first node N1. The driving transistor DT may be turned on according to a voltage applied to the first node N1 and may control an amount of the driving current flowing to the light emitting diode LD.

In an example embodiment, the driving transistor DT may be formed of two auxiliary driving transistors DT1 and DT2 connected in series as illustrated. At this instance, a first auxiliary driving transistor DT1 may be connected between the high potential driving voltage VDD and the second auxiliary driving transistor DT2, and a second auxiliary driving transistor DT2 may be connected between the first auxiliary driving transistor DT1 and the first node N1. A gate electrode of the first auxiliary driving transistor DT1 and the second auxiliary driving transistor DT2 may be connected to the first node N1. However, the example embodiments are not limited thereto.

The first electrode of the first transistor T1 is connected to the data line DL, and the second electrode thereof is indirectly connected to the gate electrode of the driving transistor DT through the third node N3. A gate electrode of the first transistor T1 may be connected to the first scan line GL1 and may receive a first scan signal SC1. The first transistor T1 may be turned on according to the first scan signal SC1 applied to the first scan line GL1, and transfer the data voltage Vdata applied to the data line DL to the third node N3. Such a first transistor T1 may be referred to as a switching transistor.

A first electrode of the second transistor T2 is connected to the gate electrode of the driving transistor DT through the first node N1, and a second electrode thereof is connected to the second electrode of the driving transistor DT through the second node N2. A gate electrode of the second transistor T2 may be connected to the second scan line GL2 and may receive a second scan signal SC2. The second transistor T2 may be turned on according to the second scan signal SC2 applied to the second scan line GL2, and may electrically connect the gate electrode of the driving transistor DT and the second electrode to each other.

A first electrode of the third transistor T3 is configured to receive the reference voltage Vref (connected to the reference voltage line VrefL), and a second electrode thereof is connected to the third node N3. A gate electrode of the third transistor T3 may be connected to the light emission line EL and may receive a light emission signal EM. The third transistor T3 may be turned on according to the light emission signal EM applied to the light emission line EL and may apply the reference voltage Vref to the third node N3. Such a third transistor T3 may be referred to as an initialization transistor.

A first electrode of the fourth transistor T4 is connected to the driving transistor DT through the second node N2, and a second electrode thereof is connected to the light emitting diode LD through a fourth node N4. A gate electrode of the fourth transistor T4 may be connected to the light emission line EL and may receive the light emission signal EM. The fourth transistor T4 may be turned on according to the light emission signal EM applied to the light emission line EL and may connect the driving transistor DT and the light emitting diode LD. When the fourth transistor T4 is turned on, a current path is formed between the high potential driving voltage VDD and the low potential driving voltage VSS, and the light emitting diode LD may emit light. Such a fourth transistor T4 may be referred to as a light emission transistor.

A first electrode of a fifth transistor T5 is configured to receive the reference voltage Vref (connected to the reference voltage line VrefL), and a second electrode thereof is connected to an anode electrode of the light emitting diode LD through the fourth node N4. A gate electrode of the fifth transistor T5 may be connected to the second scan line GL2 and may receive the second scan signal SC2. The fifth transistor T5 may be turned on according to the second scan signal SC2 applied to the second scan line GL2, and may transfer the reference voltage Vref to the anode electrode of the light emitting diode LD. Such a fifth transistor T5 may be referred to as an anode initialization transistor.

The capacitor Cst may be connected between the first node N1 and the third node N3. The capacitor Cst may store a voltage in correspondence with a difference between the first node N1 and the third node N3.

An anode electrode of the light emitting diode LD may be connected to the fourth node N4, and a cathode electrode thereof may be connected to the low potential driving voltage VSS. When the driving transistor DT and the fourth transistor T4 are turned on, a current path may be formed between the high potential driving voltage VDD and the low potential driving voltage VSS and the driving current may flow to the light emitting diode LD. The light emitting diode LD may emit light at luminance corresponding to the applied driving current.

In the example embodiment illustrated in FIG. 12, the pixel PX may be configured of a low temperature poly silicon (LTPS) thin film transistor. The LTPS thin film transistor includes a gate electrode, a source electrode, and a drain electrode. The LTPS thin film transistor may have an active layer formed of poly silicon. Such an LTPS thin film transistor may be formed of a p type thin film transistor, or an n type thin film transistor. The LTPS thin film transistor has a high electron mobility, and therefore, has a fast driving characteristic.

In another example embodiment, the pixel PX may be formed of an oxide semiconductor thin film transistor, or may be a hybrid type which includes the LTPS thin film transistor and the oxide thin film transistor. The oxide semiconductor thin film transistor may include a gate electrode, a source electrode, and a drain electrode. The oxide semiconductor thin film transistor has an active layer formed of an oxide semiconductor. Here, the oxide semiconductor may be set as an amorphous oxide semiconductor or a crystalline oxide semiconductor. The oxide semiconductor thin film transistor may be configured as a p-type transistor, or an n-type transistor. The oxide semiconductor thin film transistor may be formed through a low temperature process and has a lower charge mobility than that of the LTPS thin film transistor. Such an oxide semiconductor thin film transistor has an excellent off current characteristic.

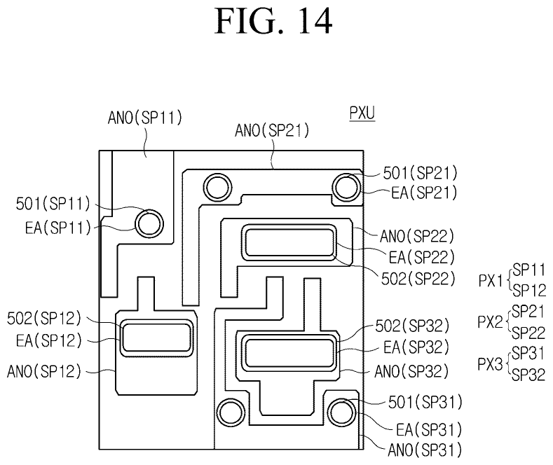

FIG. 14 is a plan view illustrating a unit pixel according to an example embodiment. In more detail, FIG. 14 illustrates an upper plane of the unit pixel PXU, when three pixels PX1, PX2 and PX3 are disposed in the unit pixel PXU, and each of the pixels PX1, PX2 and PX3 includes two sub-pixels SP11, SP12, SP21, SP22, SP31 and SP32.

Each of the sub-pixels SP11, SP12, SP21, SP22, SP31 and SP32 includes the light emitting diode LD (FIG. 12). The light emitting diode LD includes an anode electrode ANO.

Each of the sub-pixels SP11, SP12, SP21, SP22, SP31 and SP32 has a light emitting region EA defined by the light emitting diodes LD. The light emitting region EA may be defined as a region in which the anode electrode ANO is not covered by an upper insulating layer (for example, a bank which will be described below) and is exposed to an upper side. A size and a shape of the light emitting region EA of the sub-pixels SP11, SP12, SP21, SP22, SP31 and SP32 may be the same or different from one another. In an example embodiment, the light emitting region EA of the first sub-pixels SP11, SP21 and SP31 may have a circular shape in general, and a light emitting region of the second sub-pixels SP12, SP22 and SP32 may have a quadrangular shape in general, but are not limited thereto.

In an example embodiment, the first, second and third pixels PX1, PX2 and PX3 may be red, green, and blue pixels, respectively. Therefore, the light emitting diode LD of the sub-pixels SP11 and SP12 of the first pixel PX1 may emit red light, the light emitting diode LD of the sub-pixels SP21 and SP22 of the second pixel PX2 may emit green light, and the light emitting diode LD of the sub-pixels SP31 and SP32 of the third pixels PX3 may emit blue light.

On each of the sub-pixels SP11, SP12, SP21, SP22, SP31, and SP32, a lens member which includes a plurality of lenses 501 and 502 is disposed. The lens member may include a first lens 501 and a second lens 502, each of which provides a different viewing angle. For example, the first lens 501 may be disposed in the light emitting regions EA of the first sub-pixels SP11, SP21, and SP31, and the second lens 502 may be disposed in the light emitting regions EA of the second sub-pixels SP12, SP22, and SP32.

A size and a shape of the first lens 501 or the second lens 502 may be different from each other so as to provide each different viewing angle. For example, the first lens 501 may be a hemispherical lens having a flat lower surface and a spherical upper surface, opposite the lower surface. For example, the second lens 502 may be a semicylindrical lens having a flat lower surface and a semi-cylindrical upper surface, opposite the lower surface. However, the example embodiment is not limited thereto.

Through the first lens 501 and the second lens 502 having each different shape, a viewing angle of the display panel 50 may be controlled. In more detail, directions of viewing angle limitation of the first lens 501 and the second lens 502 are different from each other, and a narrow viewing angle and a wide viewing angle may be implemented through above-described selective driving of the sub-pixels SP11, SP12, SP21, SP22, SP31, and SP32.

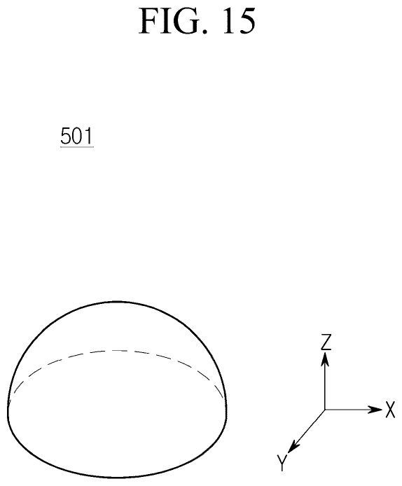

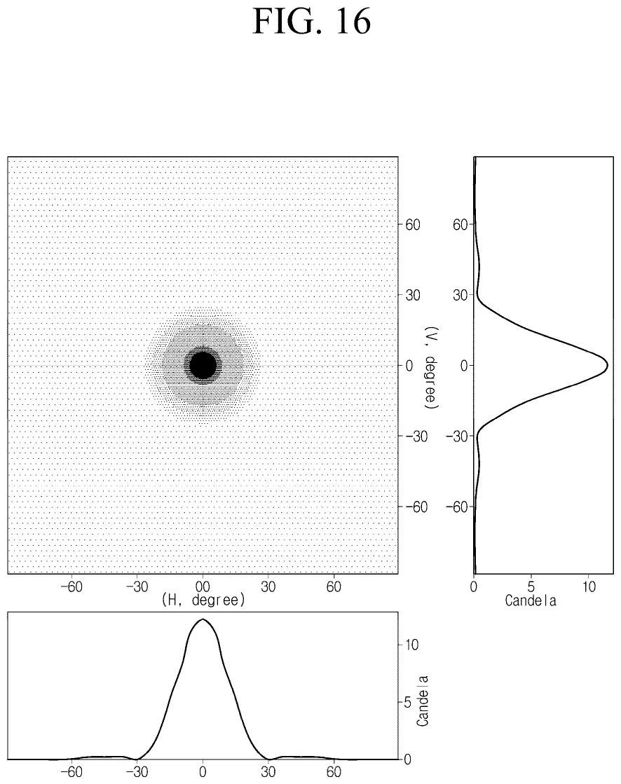

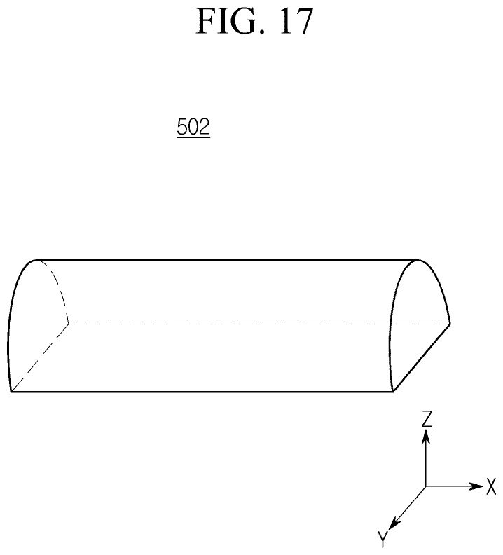

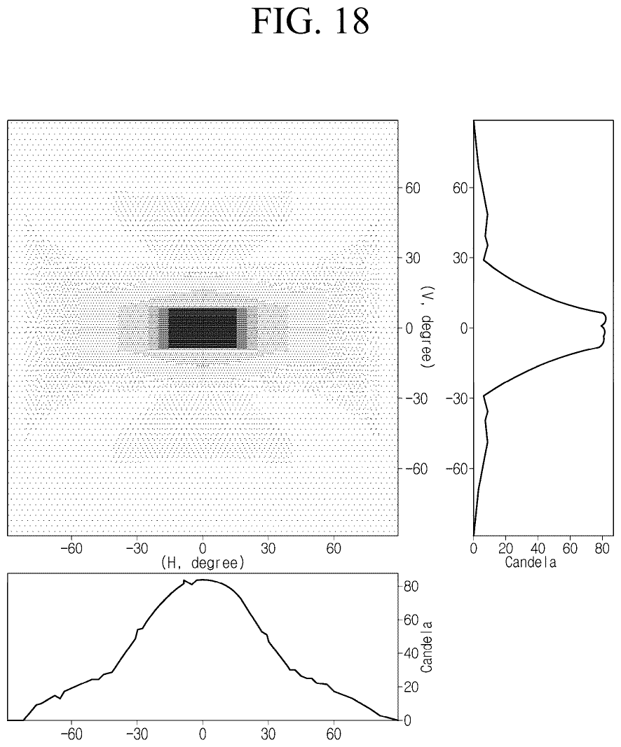

FIG. 15 is a view schematically illustrating the first lens illustrated in FIG. 14. FIG. 16 is a view illustrating an optical profile with respect to a viewing angle of the first lens illustrated in FIG. 15. FIG. 17 is a view schematically illustrating the second lens illustrated in FIG. 14. FIG. 18 is a view illustrating an optical profile with respect to a viewing angle of the second lens illustrated in FIG. 17.

As illustrated in FIG. 15, the first lens 501 is a hemispherical lens and has a semicircular cross-section in X and Y directions. Therefore, the first lens 501 limits a viewing angle in the X and Y directions.

On the contrary, as illustrated in FIG. 17, the second lens 502 is a semicylindrical lens and has a rectangular cross-section in the X direction, and a semicircular cross-section in the Y direction. Therefore, the second lens 502 limits a viewing angle in the Y direction, and does not limit a viewing angle in the longitudinal direction of the first lens 501, that is, a viewing angle in the X direction.

As illustrated in FIG. 16, the light emitting regions EA11, EA21 and EA31 (FIG. 14) of the first sub-pixels SP11, SP21 and SP31 (FIG. 14) in which the hemispherical first lens 501 is provided have a narrow viewing angle of about 30 degrees or less in both left and right directions and a vertical direction. On the contrary, as illustrated in FIG. 18, the light emitting regions EA12, EA22 and EA32 (FIG. 14) of the second sub-pixels SP12, SP22 and SP32 (FIG. 14) in which the semicylindrical second lens 502 is provided have a wide viewing angle of about 60 degrees or more in the left and right directions.

Therefore, a narrow viewing angle mode in the vertical direction and a narrow viewing angle mode in the left and right directions (that is, the privacy mode) may be implemented with respect to the first image displayed in the first sub-pixels PS11, SP21 and SP31, and the narrow viewing angle mode in the vertical direction and a wide viewing angle mode in the left and right directions (that is, the share mode) may be implemented with respect to the second image displayed in the second sub-pixels SP12, SP22 and SP32.

As such, the display panel 50 (FIG. 1) has a narrow viewing angle in the vertical direction all the time, and therefore, the display panel 50 may prevent an image from being reflected on a front glass of the vehicle and interrupting a sight of the driver when it is applied in the vehicle.

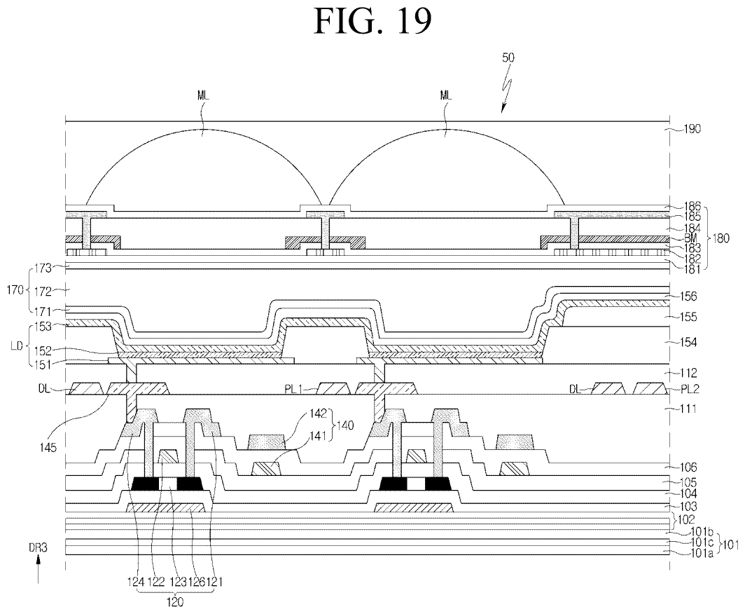

FIG. 19 is a schematic cross-sectional view of the display region of the display panel according to an example embodiment. In FIG. 19, a cross-section of the two sub-pixels SP disposed adjacent to each other is illustrated. In particular, in FIG. 19, a cross-section of the first sub-pixels configured to display the first image is illustrated.

Referring to FIG. 19, the display panel 100 may include the substrate 101, a thin film transistor 120, the light emitting diode LD, an encapsulation unit 170, and a touch unit 180.

The substrate 101 may include one or more plastic materials such as polyimide and the like, or a glass material. The substrate 101 may be a rigid substrate or a flexible substrate.

A buffer layer 102 may be disposed on the substrate 101. The buffer layer 102 may minimize or delay dispersion of moisture or oxygen permeating the substrate 101. The buffer layer 102 may be formed by alternately stacking silicon nitride SiNx and silicon oxide SiOx at least once, but is not limited thereto. In FIG. 19, the buffer layer 102 is illustrated as a multi-structured layer configured with three layers, but a quantity of layers configuring the buffer layer 102 is not limited thereto, and the buffer layer 102 may be formed as a single-structured layer.

A light shielding layer 126 may be disposed on the buffer layer 102. The semiconductor layer 123 may be disposed to overlap the light shielding layer 126. The light shielding layer 126 may prevent transmission of light into the semiconductor layer 123 of the thin film transistor 120. The light shielding layer 126 may be formed of a metal material, and may be a single-structured layer or a multi-structured layer formed of one among molybdenum (Mo), aluminum (Al), chrome (Cr), nickel (Ni), neodymium (Nd), and copper (Cu), or an alloy thereof, but is not limited thereto.

A first insulating layer 103 may be disposed on the light shielding layer 126. The first insulating layer 103 may be formed of the same material as the buffer layer 102, but the example embodiments of the present disclosure are not limited thereto.

The thin film transistor 120 may be disposed on the first insulating layer 103. The thin film transistor 120 may include a source electrode 121, a gate electrode 122, the semiconductor layer 123, and a drain electrode 124.

The semiconductor layer 123 may be disposed on the first insulating layer 103. The semiconductor layer 123 may include a source region, a drain region, and a channel region between the source region and the drain region. The semiconductor layer 123 may include an oxide semiconductor such as Indium-Gallium-Zinc Oxide (IGZO) etc., and a silicon-based semiconductor material such as amorphous silicon or polycrystalline silicon, etc., but the example embodiments of the present disclosure are not limited thereto.

A second insulating layer 104 may be disposed on the semiconductor layer 123. The second insulating layer 104 may be formed of the same material as the first insulating layer 103; however, the example embodiments of the present disclosure are not limited thereto.

The gate electrode 122 may be disposed on the second insulating layer 104. The gate electrode 122 may be disposed to overlap the channel region of the semiconductor layer 123. The gate electrode 122 may be formed of a metal material.

A third insulating layer 105 and a fourth insulating layer 106 may be disposed on the gate electrode 122. The source electrode 121 and the drain electrode 124 may be disposed on the fourth insulating layer 106. The source electrode 121 and the drain electrode 124 may be electrically connected to the semiconductor layer 123 through a contact hole. The source electrode 121 and the drain electrode 124 may be formed of a metal material.

A storage electrode 140 may be disposed to be spaced apart from the first thin film transistor 120. The storage electrode 140 may include a first storage electrode 141, and a second storage electrode 142.

The first storage electrode 141 may be disposed on the third insulating layer 105. The second storage electrode 142 may be disposed to overlap the first storage electrode 141 in at least one region, and may be disposed on the fourth insulating layer 106.

The thin film transistor 120 may be a driving transistor DT (FIG. 12), and though not illustrated, the display panel 50 may further include a transistor.

A first protection layer 111 may be disposed on the source electrode 121 and the drain electrode 124. The first protection layer 111 may planarize an upper portion of the thin film transistor 120, and protect the thin film transistor 120. The first protection layer 111 may be formed of an organic material. For example, the first protection layer 111 may be formed of an organic material including an acrylic resin, an epoxy resin, a phenolic resin, a polyamide resin, or a polyimide resin, but is not limited thereto.

A second protection layer 112 may be disposed on the first protection layer 111. The second protection layer 112 may be formed of the same material as the first protection layer 111, but is not limited thereto.

A connection electrode 145 may be disposed between the first protection layer 111 and the second protection layer 112. The connection electrode 145 may electrically connect the thin film transistor 120 and the light emitting diode LD.

The light emitting diode LD may be disposed on the second protection layer 112. The light emitting diode LD may include an anode electrode 151, an organic layer 152, and a cathode electrode 153.

The anode electrode 151 may be disposed on the second protection layer 112. The anode electrode 151 may be electrically connected to the thin film transistor 120 through the contact hole formed on the first protection layer 111 and the second protection layer 112. The anode electrode 151 may be a reflective electrode which reflects light, but the example embodiments of the present disclosure are not limited thereto. The anode electrode 151 may include a metal material having a high reflectance such as a deposition structure (Ti/Al/Ti) of aluminum (Al) and titanium (Ti), a deposition structure (ITO/Al/ITO) of aluminum (Al) and ITO, and an APC alloy, and may be formed in a single-layered structure or a multi-layered structure, but is not limited thereto.

A bank 154 may be formed to cover an edge of the anode electrode 151 and expose at least one region of the anode electrode 151 toward an upper portion. The bank 154 is formed to define an opening (or the light emitting region EA) of the sub-pixel SP. That is, the region of the anode electrode 151 not covered but exposed by the bank 154 may define the light emitting region of the sub-pixel SP.

The bank 154 may be formed of an organic material such as a material including a black pigment and the like, a benzocyclobutene resin, a polyimide resin, an acrylic resin, or photosensitive polymer, but the example embodiments of the present disclosure are not limited thereto.

A spacer 155 may be further disposed on the bank 154. The spacer 155 may be formed of the same material as a material of the bank 154, but the example embodiments of the present disclosure are not limited thereto. The spacer 155 may suppress or prevent mark or scratch defects on the display panel 50 by preventing sagging of a mask when performing a mask process.

The organic layer 152 may be disposed on the exposed region of the anode electrode 151 which is not covered by the bank. In other words, the organic layer 152 may be disposed on the exposed anode electrode 151 exposed by the bank 154. In another example embodiment, the organic layer 152 may be disposed on an entire surface of the substrate.

The cathode electrode 153 may be disposed on the organic layer 152. The cathode electrode 153 may be a transparent electrode which transmits light, but is not limited thereto. For example, the cathode electrode 153 may include a transparent conductive material or metal such as Indium Tin Oxide (ITO) or Indium Zinc Oxide (IZO) through which the visible light is transmitted, but is not limited thereto.

A capping layer 156 may be further disposed on the cathode electrode 153. The capping layer 156 may minimize damage caused by an external light source to the cathode electrode 153 of the light emitting diode LD and the organic layer 152 below the cathode electrode 153. The capping layer 156 may be formed of an organic or inorganic film.

The encapsulation unit 170 may be disposed on the bank 154 or the light emitting diode LD. The encapsulation unit 170 may include one or more insulating layers. For example, the encapsulation unit 170 may include a first inorganic encapsulation layer 171, an organic encapsulation layer 172 disposed on the first inorganic encapsulation layer 171, and a second inorganic encapsulation layer 173 disposed on the organic encapsulation layer 172. The encapsulation unit 170 may include one or more inorganic material layers and one or more organic material layers. For example, the first inorganic encapsulation layer 171 and the second inorganic encapsulation layer 173 may include an inorganic material, and the organic encapsulation layer 172 may include an organic material, but are not limited thereto.

The touch unit 180 may be disposed on the encapsulation unit 170. The touch unit 180 may include a touch buffer layer 181, a first touch electrode 182, a first touch insulating layer 183, a black matrix BM, a second touch insulating layer 184, a second touch electrode 185, and a third touch insulating layer 186.

The touch buffer layer 181 may be disposed on the encapsulation unit 170. The touch buffer layer 181 may be formed of the same material as the buffer layer 102, but is not limited thereto.

The first touch electrode 182 may be disposed on the touch buffer layer 181. The first touch insulating layer 183 may be disposed on the first touch electrode 182.

The black matrix BM may be disposed on the first touch insulating layer 183. The black matrix BM may include a material which can absorb the light.

The second touch insulating layer 184 may be disposed on the black matrix BM. The second touch insulating layer 184 may include an organic insulation material.

The second touch electrode 185 may be disposed on the second touch insulating layer 184. The first touch electrode 182 may be electrically connected to the second touch electrode 185 through the contact hole formed in the second touch insulating layer 184. The first touch electrode 182 and the second touch electrode 185 may include a metal material.

The third touch insulating layer 186 may be disposed on the second touch electrode 185. The third touch insulating layer 186 may include the same material as the first touch insulating layer 183, but is not limited thereto.

A microlens ML may be disposed on the third touch insulating layer 186. The microlens ML may have a hemispherical shape or a semicircular shape, but is not limited thereto. A shape of the microlens ML may vary according to a size and a shape of the light emitting region EA. By disposing the microlens ML, it is possible to secure a wide viewing angle characteristic, improve luminance, and block leaking light, reflected light and the like, thereby preventing the light leakage.

A center of the microlens ML may be aligned with a center of the light emitting region EA corresponding thereto. However, the present example embodiment is not limited thereto. In another example embodiments, the center of the microlens ML may be mis-aligned with the center of the light emitting region EA. In such an embodiment, optical components configured to output light emitted from the light emitting diode LD in a direction of the microlens ML may be further disposed. Alternatively, the light emitted from the light emitting diode LD may be output in the direction of the microlens ML as some components of the light emitting diode LD are tilted.

In the illustrated example embodiment, the microlens ML is the first lens 501 (FIG. 14) having the hemispherical shape disposed in the first sub-pixel SP. However, the microlens ML is not limited thereto, and the microlens ML may be configured as the second lens 502 (FIG. 14) having the semicylindrical shape disposed in the second sub-pixel SP.

A lens protection layer 190 may be disposed on the microlens ML. The lens protection layer 190 may include an organic insulation material, but is not limited thereto. The lens protection layer 190 may protect the microlens ML by covering the microlens ML.

A refractive index of the lens protection layer 190 may be smaller than that of the microlens ML. Thus, due to a difference between the refractive index of the microlens ML and the refractive index of the lens protection layer 190, it becomes possible to prevent light which passes through the microlens ML from being reflected in a direction of the substrate 101.

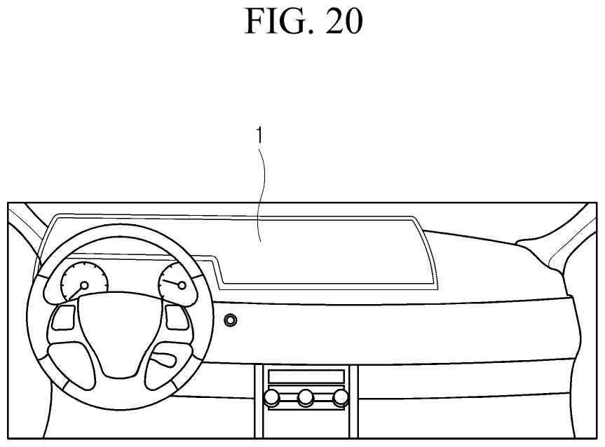

FIG. 20 is a view illustrating an example in which the display device according to an example embodiment is disposed. In more detail, FIG. 20 shows a case in which the display device 1 is disposed in a vehicle in greater detail.

Referring to FIG. 20, the display device 1 may be disposed in at least some portion of a dashboard of a vehicle. The dashboard of a vehicle includes a configuration disposed on a front surface of front seats of a vehicle (for example, a driver's seat, and a front passenger's seat). For example, in the dashboard of a vehicle, an input configuration for manipulating various functions inside a vehicle (for example, an air-conditioner, an audio system, a navigation system) may be disposed.

In an example embodiment, the display device 1 may be disposed on the dashboard of a vehicle, and may operate as an input part configured to manipulate at least some of the various functions of a vehicle. The display device 1 may provide various information related to the vehicle, for example, traveling information of the vehicle (e.g., a current velocity, a remaining fuel amount, a traveled distance of the vehicle), and information of parts of the vehicle (e.g., a damage level of a tire of the vehicle).

The display device 1 may be disposed to traverse the driver's seat and the front passenger's seat disposed on a front side of the vehicle as illustrated. Users of the display device 1 may include a driver and a passenger seated on the front passenger's seat. That is, both the driver and the passenger may use the display device 1.

The display device 1 shown in FIG. 20 may correspond to at least some of the display panel 50 (FIG. 3) included in the display device 1. For example, the display device 1 illustrated in FIG. 20 may show at least some of the display region AA (FIG. 3) and the non-display region NA (FIG. 2) of the display panel 50. Other components except a portion illustrated in FIG. 20 among the components of the display device 1 may be mounted inside the vehicle.

In one or more examples, the term (1-1)th may be referred to as first-first, the term (2-1)th may be referred to as second-first, the term (1-2)th may be referred to as first-second, and the term (2-2)th may be referred to as second-second.

The embodiments of the present disclosure have been described with reference to accompanying drawings. Those of ordinary skill in the art will recognize that the present disclosure may be embodied in other specific forms without departing from its spirit or scope of the present disclosure. The described embodiments are to be considered in all respects only as illustrative and not restrictive. The scope of the present disclosure is therefore indicated by the appended claims rather than by the foregoing description. All changes which come within meaning and range of equivalency of the claims are to be embraced within the scope of the present disclosure.

What is claimed is:

1. A display device, comprising:
a display panel including a pixel;
a data driver integrated circuit including an output buffer connected to an output channel, the data driver configured to output a data voltage to the pixel through a data line; and
a multiplexer connected between the output channel and the data line, the multiplexer including a switching element controlled by a mux control signal,
wherein the pixel comprises:
a first sub-pixel connected to a first data line; and
a second sub-pixel connected to a second data line, the second sub-pixel configured to display a color that is identical to a color of the first sub-pixel,
wherein the data driver integrated circuit is configured to output a first data voltage in correspondence with a first image to the first sub-pixel and output a dummy data voltage to the second sub-pixel when the pixel is operated in a first mode, and
wherein the data driver integrated circuit is configured to output the dummy data voltage to the first sub-pixel and output a second data voltage in correspondence with a second image to the second sub-pixel when the pixel is operated in a second mode.

2. The display device of claim 1,
wherein the output channel is further connected to a node for a ground voltage.

3. The display device of claim 2,
wherein the output channel is configured to output the first data voltage output from the output buffer to the first sub-pixel and output the ground voltage to the second sub-pixel when the pixel is operated in the first mode, and
wherein the output channel is configured to output the ground voltage to the first sub-pixel and output the second data voltage output from the output buffer to the second sub-pixel when the pixel is operated in the second mode.

4. The display device of claim 3,
wherein the output buffer is configured to be activated according to a source output enable signal at a turn-on level input from an external device, and
wherein the source output enable signal is applied at a turn-off level while the ground voltage is output from the output channel.

5. The display device of claim 1,
wherein the multiplexer comprises:
a first switching element configured to be turned on according to a first mux control signal and connect the output channel to the first sub-pixel;
a second switching element configured to be turned on according to a second mux control signal and connect the output channel to the second sub-pixel;
a first dummy switching element configured to be turned on according to a first dummy mux control signal and connect a dummy voltage line receiving the dummy data voltage and the first data line to each other; and
a second dummy switching element configured to be turned on according to a second dummy mux control signal and connect the dummy voltage line and the second data line to each other.

6. The display device of claim 5,
wherein the dummy data voltage is a voltage in correspondence with a black gray scale.

7. The display device of claim 5,
wherein the second dummy mux control signal at a turn-on level is applied when the pixel is operated in the first mode, and
wherein the first dummy mux control signal at a turn-on level is applied when the pixel is operated in the second mode.

8. The display device of claim 7,
wherein the data driver integrated circuit is configured to be activated according to a data driver enable signal input from an external device, and
wherein the data driver enable signal at a turn-off level is applied in response to the first dummy mux control signal at a turn-on level or the second dummy mux control signal at a turn-on level.

9. The display device of claim 1,
wherein the display panel comprises:
a first unit pixel and a second unit pixel, each of which comprises two or more pixels,
wherein the multiplexer comprises:
a first switching element configured to be turned on according to a first-first mux control signal and connect the output channel to the first sub-pixel of the first unit pixel;
a second switching element configured to be turned on according to a second-first mux control signal and connect the output channel to the second sub-pixel of the first unit pixel;
a third switching element configured to be turned on according to a first-second mux control signal and connect the output channel to the first sub-pixel of the second unit pixel; and
a fourth switching element configured to be turned on according to a second-second mux control signal and connect the output channel to the second sub-pixel of the second unit pixel.

10. The display device of claim 1,
wherein the display panel comprises:
a first region in which the first image is to be displayed using the first sub-pixel; and
a second region in which the second image different from the first image is to be displayed using the second sub-pixel, and
wherein the first region and the second region are varied while the display panel is driven.

11. The display device of claim 1,
wherein the first sub-pixel and the second sub-pixel have an identical pixel structure, and
wherein the first sub-pixel and the second sub-pixel have a mirrored shape along a pixel column direction.

12. The display device of claim 1,
wherein the display panel comprises a lens member, the lens member including a plurality of lenses, and
wherein the lens member comprises:
a first lens disposed in a first light emitting region of the first sub-pixel; and
a second lens disposed in a second light emitting region of the second sub-pixel, the second lens having a shape different from a shape of the first lens.

13. The display device of claim 12,
wherein the first lens is configured to control to emit light, emitted from the first light emitting region, at a first viewing angle, and
wherein the second lens is configured to control to emit light, emitted from the second light emitting region, at a second viewing angle wider than the first viewing angle.

14. A method for driving a display device, wherein the display device comprises: a display panel, the display panel including a pixel; a data driver integrated circuit including an output buffer connected to an output channel, the data driver configured to output a data voltage to the pixel through a data line; and a multiplexer connected between the output channel and the data line, the multiplexer including a switching element controlled by a mux control signal, wherein the pixel comprises: a first sub-pixel connected to a first data line; and a second sub-pixel connected to a second data line, the second sub-pixel configured to display a color identical to a color of the first sub-pixel, and wherein the method comprises:
outputting, by the data driver integrated circuit, the data voltage to the first sub-pixel in a first period within one horizontal period; and
outputting, by the data driver integrated circuit, the data voltage to the second sub-pixel in a second period within the one horizontal period.

15. The method for driving the display device of claim 14,
wherein when the pixel is operated in a first mode, the outputting the data voltage to the first sub-pixel comprises:
outputting a first data voltage output from the output buffer to the output channel, and
wherein when the pixel is operated in the first mode, the outputting the data voltage to the second sub-pixel comprises:
outputting a ground voltage to the output channel.

16. The method for driving the display device of claim 15,
wherein when the pixel is operated in a second mode, the outputting the data voltage to the first sub-pixel comprises:
outputting the ground voltage to the output channel, and
wherein when the pixel is operated in the second mode, the outputting the data voltage to the second sub-pixel comprises:
outputting a second data voltage output from the output buffer to the output channel.

17. The method for driving the display device of claim 15,
wherein the outputting the data voltage to the first sub-pixel further comprises:
activating the output buffer in response to a source output enable signal at a turn-on level, and
wherein the outputting the data voltage to the second sub-pixel further comprises:
deactivating the output buffer in response to the source output enable signal at a turn-off level.

18. The method for driving the display device of claim 14,
wherein when the pixel is operated in a first mode, the outputting the data voltage to the first sub-pixel comprises:
connecting, by the multiplexer, the output buffer to the first data line in response to a first mux control signal at a turn-on level, and
wherein when the pixel is operated in the first mode, the outputting the data voltage to the second sub-pixel comprises:
connecting, by the multiplexer, a dummy voltage line to the second data line in response to a second dummy mux control signal at a turn-on level.

19. The method for driving the display device of claim 18,
wherein when the pixel is operated in a second mode, the outputting the data voltage to the first sub-pixel comprises:
connecting, by the multiplexer, the dummy voltage line to the first data line in response to a first dummy mux control signal at a turn-on level, and
wherein when the pixel is operated in the second mode, the outputting the data voltage to the second sub-pixel comprises:
connecting, by the multiplexer, the output buffer to the second data line in response to a second mux control signal at a turn-on level.

20. The method for driving the display device of claim 18,
wherein the outputting the data voltage to the first sub-pixel further comprises:
activating the data driver integrated circuit in response to a data driver enable signal at a turn-on level, and
wherein the outputting the data voltage to the second sub-pixel further comprises:
deactivating the data driver integrated circuit in response to the data driver enable signal at a turn-off level.
